(19) United States
(12) Patent Application Publication
(10) Pub. No.: US 2007/0266291 A1
(43) Pub. Date: Nov. 15, 2007

(54) SEMICONDUCTOR MEMORY DEVICE

(75) Inventors: Haruki TODA, Yokohama-shi (JP); Toshiaki Edahiro, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/691,636

(22) Filed: Mar. 27, 2007

(30) Foreign Application Priority Data
May 15, 2006 (JP) 2006-135025

(51) Int. Cl. G06F 11/00; H03M 13/00

(52) U.S. Cl. 714/746; 714/782

(57) ABSTRACT

A semiconductor memory device including an error detection and correction system, wherein the error detection and correction system has a first operation mode for correcting one number-bit (for example 2) errors and a second operation mode for correcting another number-bit (for example 1) error(s), which are exchangeable to be set with a main portion of the system used in common.

### CROSS-REFERENCE TO RELATED APPLICATION

This application is based on and claims the benefit of priority from the prior Japanese Patent Application No. 2006-135025, filed on May 15, 2006, the entire contents of which are incorporated herein by reference.

### BACKGROUND OF THE INVENTION

1. Field of the Invention

This invention relates to a semiconductor memory device, and more specifically, to an error detection and correction system integrally formed in the device.

2. Description of the Related Art

Electrically rewritable and non-volatile semiconductor memory devices, i.e., flash memories, increase in error rate with an increase in number of data rewrite operations. In particular, the further enhancement of the storage capacity increase and miniaturization results in the error rate increase. In view of this, an attempt is made to mount a built-in error correcting code (ECC) circuit on flash memory chips or memory controllers of these memories. An exemplary device using this technique is disclosed, for example, in JP-A-2000-173289.

A host device using a flash memory is desirable to have an ECC system, which detects and corrects errors occurred in the flash memory. In this case, however, the host device increases in its workload when the error rate is increased. For example, it is known that a 2-bit error correctable ECC system becomes large in calculation scale, as suggested by JP-A-2004-152300.

Accordingly, in order to cope with such error rate increase while suppressing the load increase of the host device, it is desired to mount a 2-bit error correctable ECC system on the memory chip. What is needed in this case is to increase the arithmetic operation speed of the ECC system, and suppress the penalties of read/write speed reduction of the flash memory.

### SUMMARY OF THE INVENTION

According to an aspect of the present invention, there is provided a semiconductor memory device including an error detection and correction system, wherein

the error detection and correction system has a first operation mode for correcting one number-bit errors and a second operation mode for correcting another number-bit error(s), which are exchangeable to be set with a main portion of the system used in common.

According to another aspect of the present invention, there is provided a semiconductor memory device including a cell array with electrically rewritable and non-volatile semiconductor memory cells arranged therein and an error detection and correction system, which is correctable up to 2-bit errors for read out data of the cell array by use of a BCH code over Galois field GF(256), wherein

the error detection and correction system has a first operation mode for correcting 2-bit errors and a second operation mode for correcting 1-bit error, which are exchangeable to be set with a main portion of the system used in common.

### BRIEF DESCRIPTION OF THE DRAWINGS

FIG. 1 shows an error detecting and correcting system in a flash memory in accordance with an embodiment of the present invention.

FIG. 2 shows an example of the memory core in the flash memory.

FIG. 3 shows another example of the memory core.

FIG. 4 shows a read method in a case where the memory core shown in FIG. 3 is used.

FIG. 5 shows 4-level data threshold distribution in a case where the memory core shown in FIG. 3 is used.

FIG. 6 shows 144 degrees which are selected as data bits from the information polynomial in case of 2EC system.

FIG. 7 is a table of such “n”s that coefficients of the respective degrees are “1” in 15-degree polynomial in case of 2EC system.

FIG. 8 is a table of “n”s with coefficients of the respective degrees being “1” in 9-degree polynomial in case of 1EC system.

FIG. 9 shows parity checker ladders and input circuit thereof for constituting the encoding part shown in FIG. 1.

FIG. 10 shows an example of the parity checker ladder used in FIG. 9.

FIGS. 11A and 11B show 2-bit parity check circuit and the circuit symbol used in FIG. 9.

FIGS. 12A and 12B show 4-bit parity check circuit and the circuit symbol used in FIG. 9.

FIG. 13 shows a table of “n”s with coefficients of the respective degrees being “1” in the remainder polynomial pⁿ(x) used in the calculation of syndrome polynomial S₁(x).

FIG. 14 shows a table of “n”s with coefficients of the respective degrees being “1” in the remainder polynomial p³ⁿ(x) used in the calculation of syndrome polynomial S₃(x).

FIG. 15 shows parity checker ladders and input circuit thereof for constituting the syndrome operation part shown in FIG. 1.

FIG. 16 shows an example of the parity checker ladder used in FIG. 15.

FIG. 17 show a table of “n”s with coefficients being “1” of the respective degrees of the remainder polynomial pⁿ(x) for selected “n” used in the calculation of the syndrome polynomial S₁(x).

FIG. 18 shows an example of the parity checker ladder used in the syndrome operation.

FIG. 19 is a table designating the relationship between indexes “n” and “yₙ”

FIG. 20 shows yₙ-locator in the error location searching part shown in FIG. 1.

FIG. 21 shows i-locator in the same part.

FIG. 22 shows error correcting circuit in the same part.

FIG. 23 shows a configuration of the pre-decoder.

FIG. 24 shows a configuration of the decoding part used in each locator.

FIG. 25 shown a configuration of index/binary converting part used in each locator.

FIG. 26 shows 5-bit(17) adder used in each locator.

FIG. 27 shows the circuit symbol of the 5-bit(17) adder.

FIG. 28 shows 4-bit(15) adder used in each locator.

FIG. 29 shows the circuit symbol of the 4-bit(15) adder.

FIGS. 30A and 30B show a full adder and circuit symbol thereof used in each adder.

FIGS. 31A and 31B show a half adder and circuit symbol thereof used in each adder.

FIG. 32 shows the pre-decoder & switch used in FIG. 20.

FIG. 33 shows yₙ-decoder used in the i-locator.

FIG. 34 shows a “no-index” detecting circuit used in the i-locator.

FIG. 35 shows an error location decoding part in the error correction circuit.

FIG. 36 shows a data correction circuit used in the same error correction circuit.

FIG. 37 shows one index adder part in the yₙ-locator.

FIG. 38 shows a table, in which the indexes “n”s of pⁿ(x) are classified into the remainder class 15n(17).

FIG. 39 shows a table, in which the indexes “n”s of pⁿ(x) are classified into the remainder class −45n(17).

FIG. 40 shows the other index adder part in the yₙ-locator.

FIG. 41 shows a table, in which the indexes “n”s of pⁿ(x) are classified into the remainder class 17n(15).

FIG. 42 shows a table, in which the indexes “n”s of pⁿ(x) are classified into the remainder class −51n(15).

FIG. 43 shows an index adder part 52 in the i-locator.

FIG. 44 is a table showing the relationship between the remainder class indexes 15yₙ(17), 17yₙ(15) and 15n(17).

FIG. 45 shows another index adder part 53 in the i-locator.

FIG. 46 is a table showing the relationship between the remainder class indexes 15yₙ(17), 17yₙ(15) and 17n(15).

FIG. 47 shows the pre-decoder and error correction part in FIG. 22.

FIG. 49 shows another embodiment applied to a digital still camera.

FIG. 50 shows the internal configuration of the digital still camera.

FIGS. 51A to 51J show other electric devices to which the embodiment is applied.

### DETAILED DESCRIPTION OF THE EMBODIMENTS

Previously to the detailed explanation of the embodiments, background and outline thereof will be explained below.

Miniaturization of the cell array and capacity-increase being enhanced in a semiconductor memory, it becomes necessary to use an error detection and correction system (ECC system) for securing the data reliability. However, to mount an ECC system, it is in need of preparing a check bit area in addition to a normal data storage area. Particularly, to achieve a high-powered ECC system, it is required to prepare a large check bit area.

That is, to secure the data reliability, it is necessary to take a large check bit area, while increasing of the check bit area leads to reduction of the normal data area, thereby resulting in that it takes a long time for error correcting. Therefore, the data reliability is inconsistent with the data area efficiency and error-correcting speed.

For example, in a BCH code system, which is 2-bit error correctable, i.e., 2EC-BCH system, it is necessary to generate 16 check bits and store them in addition to, for example, 128 information bits. In this case, for the ECC system, it takes an additional area of 16/128=0.125 in the memory device, i.e., it is necessary to secure a data area with an increase of 12.5%.

If it is desired to give priority to the data storage amount over the data reliability, it will be selected that the ECC system is not mounted or correctable error bit numbers are reduced. However, such the selection is not always possible in accordance with the request for data reliability. Therefore, it will be desired to construct such a system that the ECC efficiency (i.e., error correcting rate) is selectable in accordance with the using situation of the memory or the balance of the data reliability and the economy without breaking the scale and processing speed of the ECC system.

In the embodiment described below, the error correcting rate is set to be selectable in accordance with the using situation of the memory. For example, a 2EC-BCH system is basically mounted, and it is exchangeable to such a parity check code system (i.e., 1EC-2EW system) that 1-bit error is correctable while warning is generated in case of 2-bit errors. In other words, a first operation mode for performing 2-bit error correction and a second operation mode for performing 1-bit error correction are prepared to be exchangeable on condition that the main circuit portion of 2EC-BCH system is used in common as it is.

Taking notice of a detailed memory system, there are two aspects as follows:

According to a first aspect, with respect to a certain data area, two operation modes, 2EC-BCH system and 1EC-2EW system, are used to be exchangeable. In case it is required of the data area to store data with a high reliability, 2EC-BCH system is selected to be adapted, thereby increasing the number of error-correctable bits. While, to give priority to the stored data amount over the data reliability, 1EC-2EW system is selected to be adapted, so that the check bit area is made less while the normal data area is made larger. Additionally, error correction time will be shortened in comparison with the case of 2EC-BCH system. As described above, different ECC systems are selectively adapted to the certain data area.

According to a second aspect, a first data area, to which 2EC-BCH system is adapted, and a second data area, to which 1EC-BCH system is adapted, are disposed in parallel. That is, a memory device has two or more data areas with different data reliabilities required, and the number of error-correctable bits of ECC will be selected in accordance with the required data reliability of an accessed data area.

Next, embodiments of the present invention will be explained with reference to the accompanying drawings below.

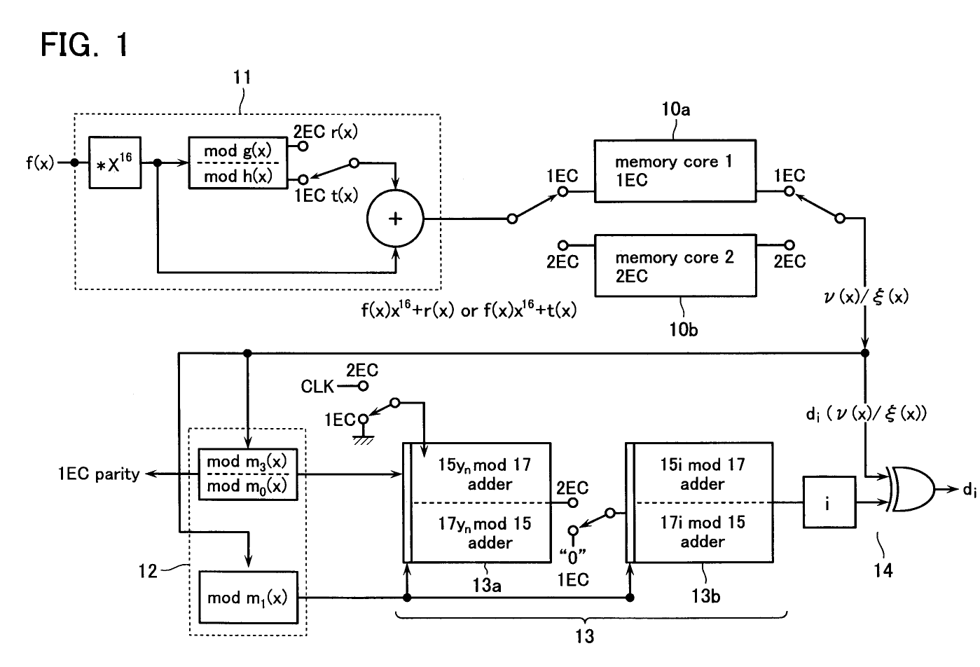

FIG. 1 shows an outline of a memory device in accordance with an embodiment, which has such a basic operation mode (or system), “2EC-EW”, that 2-bit errors are correctable while warning is generated in case of 3-bit or more errors, and the basic operation mode 2EC-EW is exchangeable to such another operation mode (system), “1EC-2EW”, that 1-bit error is correctable while warning is generated in case of 2-bit errors with a parity check code.

The above-described two operation modes (or systems) share a main circuit part of an ECC circuit, and are switched by data input exchange or sub-system shortcut. In the embodiment described below, 1EC-2EW operation mode (or system) and 2EC-EW operation mode (or system) will be often simplified and referred to as “1EC system” and “2EC system”, respectively.

In FIG. 1, memory core 10a is a 1EC-2EW system adapted area while memory core 10b is a 2EC-EW system adapted area. That is, in this case, memory cores 10a and 10b are arranged independently of each other in a memory chip, and selectively used in accordance with applications. However, the present invention is not limited to the above-described case, but is adaptable to such a case that the memory cores 10a and 10b are integrated into one area, to which 1EC-2EW system and 2EC-EW system are selectively adapted.

Encoding part 11 is for generating check bits necessary for error-detecting for to-be-written data. In case of 2EC system, 16 check bits are generated as coefficients of a remainder polynomial r(x) that is obtained by dividing a data polynomial f(x)x¹⁶ by a code generating polynomial g(x). In case of 1EC system, 9 check bits are generated as coefficients of a remainder polynomial t(x) that is obtained by dividing the data polynomial f(x)x¹⁶ by a code generating polynomial h(x).

Obtained check bits are written into the cell array of the memory core 10a or 10b together with to-be-written data bits.

Read out data from the memory core 10a or 10b is defined by a polynomial ν(x) (in case of 2EC system) or a polynomial ξ(x) (in case of 1EC system). The read out data is subjected to the syndrome calculation in the decode portion, i.e., syndrome operation part 12, for judging whether there is an error(s) or not. In case of 2EC system, syndromes will be obtained here through remainder calculation by two 8-degree primitive polynomials m₁(x) and m₃(x).

While in case of 1EC system, input/output are exchanged to execute remainder calculation by m₀(x), i.e., parity check for read out data of 128+9 bits, here in place of the remainder calculation by m₃(x).

Error location searching part 13, which is for searching an error location(s) based on the obtained syndromes, has two stages of index operation parts 13a and 13b. In case of 2EC system, variable “y” is used in place of the real variable “x” of the data polynomial through variable conversion of: x=α^{σ1}y. The first stage index operation part 13a is for obtaining index yₙ in correspondence with an error location, which will be referred to as “yₙ-locator” hereinafter. Based on the operation result of the yₙ-locator, the second stage index operation part 13b is for searching the real error bit position “i”, which will be referred to as “i-locator” hereinafter.

These locators, i.e., sub-systems, are configured to achieve addition/subtraction with modulo 255 as parallel processed addition/subtraction with modulo 17 and addition/subtraction with modulo 15. In general, supposing that the prime factors obtained by factorizing 2ⁿ−1 are A and B, addition/subtractions with modulo A and modulo B are performed simultaneously in parallel to output the addition/subtraction with modulo 2ⁿ.

Error correcting part 14 is prepared to invert the bit data at a detected error location.

In case of 1EC system, yₙ-locator 13a becomes unnecessary. To make this part inactive and short-circuit it, clock signal CLK applied to this part is fixed to be at Vss, thereby fixing the output for the next stage to be “0”. This prevents the next stage, i.e., i-locator 13b, from erroneously calculating. When one input is fixed to be “0”, there is no circuit change in the i-locator 13b except that it becomes substantially a decoder from the adder circuit.

Previously to the detailed explanation of the 2EC system and 1EC system, the memory core configuration will be explained in detail below.

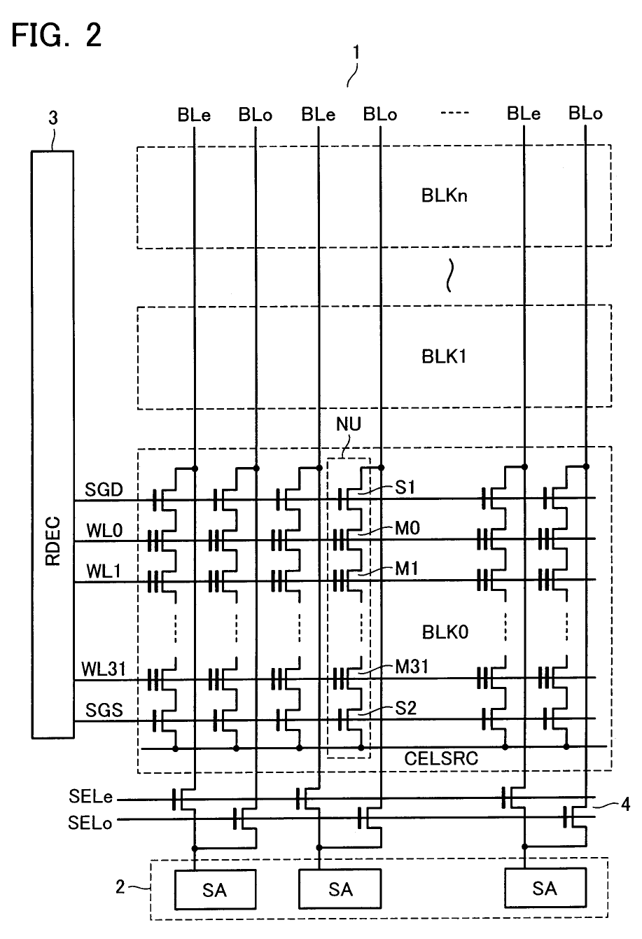

FIG. 2 shows a memory core configuration of a NAND-type flash memory in accordance with this embodiment, which has cell array 1, sense amplifier circuit 2 and row decoder 3. The cell array 1 has NAND cell units (i.e., NAND strings) NU arranged therein, each of which has thirty two memory cells M0-M31 connected in series. One end of NAND cell units NU is coupled to a bit line BLe (BLo) via a select gate transistor S1; and the other end to a common source line CELSRC via another select gate transistor S2.

Control gates of the memory cells are coupled to word lines WL0-WL31, respectively; and gates of the select gate transistors S1 and S2 to select gate lines SGD and SGS, respectively. Row decoder 3 is prepared for selectively driving the word lines WL0-WL31 and select gate lines SGD and SGS.

The sense amplifier circuit 2 has multiple sense units SA necessary for simultaneously writing/reading one page data. To each sense amplifier SA, either one of adjacent two bit lines BLe and BLo is coupled, which is selected with bit line select circuit 4. As a result, a set of memory cells selected by one word line and multiple even numbered bit lines (or multiple odd numbered bit lines) constitutes a page (one sector) subjected to simultaneous write/read. In this case, non-selected bit lines are used as shield lines with a certain voltage applied, and this prevents the selected bit line data from being influenced with interference between bit lines.

A set of NAND cell units sharing word lines constitutes a block, which serves as an erase unit, and multiple blocks BLK0-BLKn are arranged in the bit line direction as shown in FIG. 2.

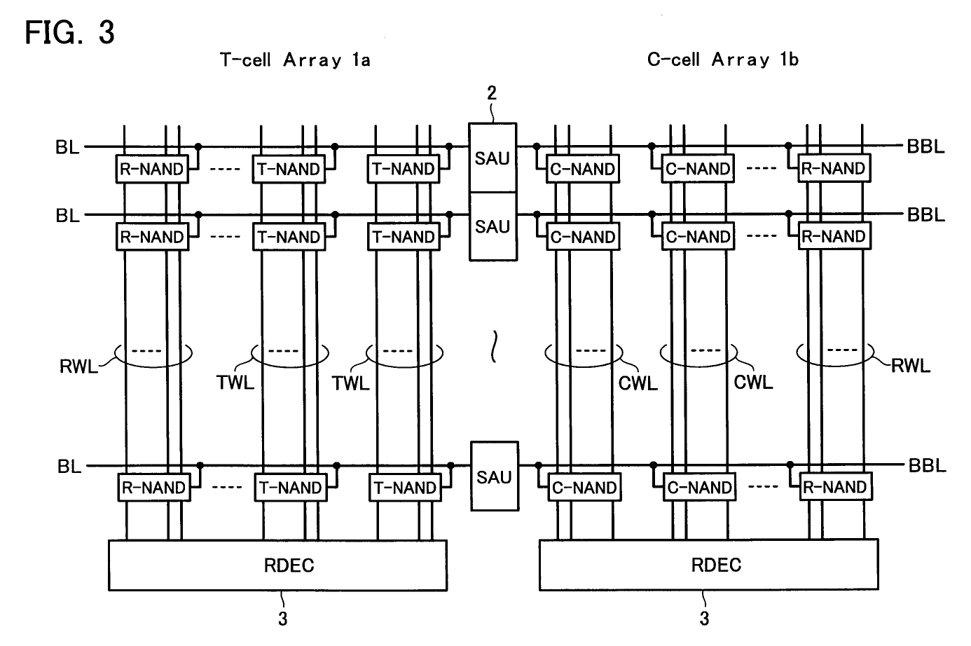

FIG. 3 shows another memory core configuration of a NAND-type flash memory with an operation principle different from the above-described one.

A memory cell array 1 is divided into two cell arrays, i.e., T-cell array 1a and C-cell array 1b, which are disposed to sandwich a sense amplifier circuit 2. The sense amplifier circuit 2 is formed to have such a current-detecting type sense amplifier that detects cell current difference between an “information cell” (T-cell or C-cell) selected from one of the cell array 1a and 1b and a “reference cell” (R-cell) selected from the other, thereby sensing cell data.

In the cell array 1a, multiple information cell NAND strings, T-NAND, and at least one reference cell NAND string, R-NAND are disposed along a bit line BL to be selectively coupled to it. In the cell array 1b, multiple information cell NAND strings, C-NAND, and at least one reference cell NAND string, R-NAND, are disposed along a bit line BBL to be selectively coupled to it, which constitutes a pair together with the bit line BL in the cell array 1a.

The information cell T-cell, C-cell and the reference cell R-cell has the same cell structure. When an information cell T-cell (or C-cell) is selected from one cell array, a reference cell R-cell is selected from the other cell array.

Information cell NAND strings T-NAND, C-NAND and reference cell NAND strings R-NAND each are arranged in perpendicular to the bit line to constitute cell blocks, respectively. Word line TWL, CWL and RWL are disposed in common to the cell blocks, respectively.

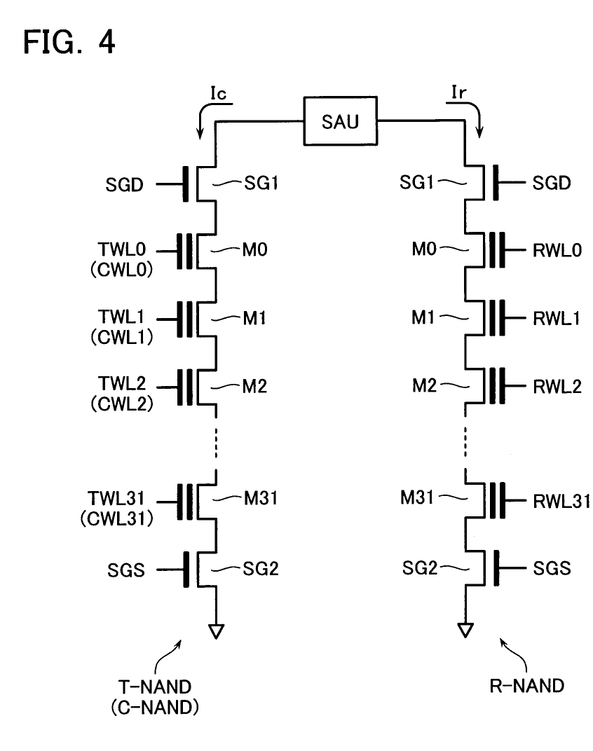

FIG. 4 shows such a situation that an information cell NAND string T-NAND (or C-NAND) and a reference cell NAND string R-NAND are coupled to a sense unit SAU. As shown in FIG. 4, each NAND string has electrically rewritable and non-volatile memory cells M0-M31 connected in series and select gate transistors SG1 and SG2. Although non-volatile memory cells M0-M31 in the information cell NAND string are the same as in the reference cell NAND string, they serve as information cells T-cell (or C-cell) in the information cell NAND string, and reference cells R-cell in the reference cell NAND string.

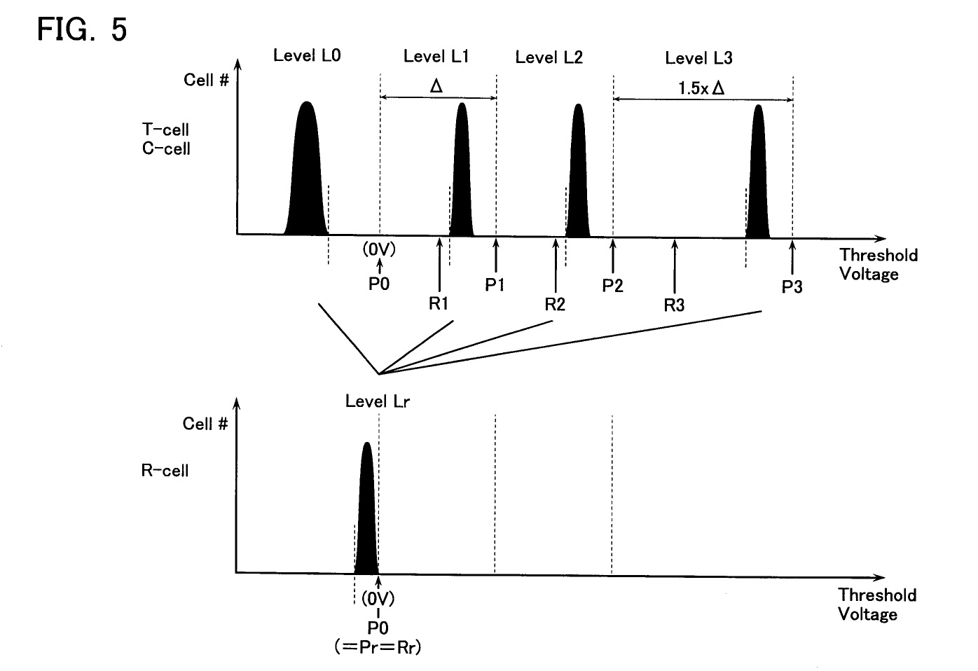

FIG. 5 shows a data level distribution (threshold distribution) of memory cells in case of a 4-level data storage scheme (i.e., 2 bits/cell scheme) is adapted. In general, it will be used such a multi-level storage scheme that two or more bits are stored in each memory cell. Written into the information cell T-cell or C-cell is one of four data levels L0, L1, L2 and L3 while written into the reference cell R-cell is a reference level Lr that is, for example, set to be between data levels L0 and L1.

For example, the information cells T-cell and C-cell have different bit assignments for four data levels L0 to L3 from each other. In one example, four data levels being expressed by (HB, LB), where HB is an upper bit HB; and LB lower bit, bit assignment of the information cell T-cell in the cell array 1a is set as follows: L0=(1, 0), L1=(1, 1), L2=(0, 1) and L3=(0, 0) while that of the information cell C-cell in the cell array 1b is set as follows: L0=(0, 0), L1=(0, 1), L2=(1, 1) and L3=(1, 0).

In FIG. 5, read voltages R1, R2 and R3 applied to the information cell T-cell or C-cell in accordance with to-be-read data and read voltage Rr applied to the reference cell R-cell are shown, which are used in a read mode. There are also shown in FIG. 5 write verify-read voltages P1, P2 and P3 applied to the information cell T-cell or C-cell and that Pr applied to the reference cell R-cell at a data write time.

The four-level data storage scheme described above is preferable in such a case that it is in need of storing a large amount of data such as image data. Therefore, in this scheme, 1EC system with a small check bit area will be used. By contrast, in such a case that it is in need of securing a high data reliability, binary data storage scheme is preferable, and 2EC system with a large check bit area will be used.

Next, 2EC-EW system and 1EC-2EW system will be explained in detail below. In this embodiment, 2EC-BCH system is used to be adaptable to 2EC system. Therefore, firstly, the basic 2EC-BCH system will be explained.

### (Data Encoding in 2EC System)

Supposing that 128-bit data are used as a unit for error-detection and correction, 2EC-BCH code necessary for 2-bit error correcting is formed as one over Galois field GF(256). In this case, the usable maximum bit length is 28-1=255; and necessary check bits are 16.

The primitive root (element) of Galois field GF(256) being α, 8-degree primitive polynomial m₁(x) on the ground field GF(2) with this element a being as its own root is represented by Expression 1. In other words, irreducible polynomials of a power of a and a power of x due to m₁(x) become mutually corresponding elements in GF(256). Additionally, as another 8-degree irreducible polynomial with a cubic of α being its root, polynomial m₃(x) that is prime with m₁(x) is used as shown in the Expression 1.

α: m₁ (x)=x⁸+x⁴+x³+x²+1

α³: m₃ (x)=x⁸+x⁶+x⁵+x⁴+x²+x+1 [Exp. 1]

Based on these two primitive polynomials, a 2-bit error correctable ECC system (i.e., 2EC-BCH system) will be configured. To generate check bits based on to-be-written data, a product polynomial g(x) of m₁(x) and m₃(x) is prepared as a code generating polynomial g(x) as shown in Expression 2 below.

$$\begin{matrix}g ( x ) = {m}_{1} ( x ) {m}_{3} ( x ) \\ = {x}^{16} + {x}^{14} + {x}^{13} + {x}^{11} + {x}^{10} + {x}^{9} + {x}^{8} + {x}^{6} + \\ {x}^{5} + x + 1\end{matrix} \qquad [ Exp . 2 ]$$

A maximum number of two-bit error correctable bits capable of being utilized as information bits is 239. Coefficients from bit position 16 to 254 being a₁₆ to a₂₅₄, a 238-degree information polynomial f(x) is represented as shown in Expression 3.

f(x)=a₂₅₄x²³⁸+a₂₅₃x²³⁷+ . . . +a₁₈x²+a₁₇x+a₁₆ [Exp. 3]

Supposing that actually used are 128 bits in 239 bits as described above, coefficients corresponding to the remaining 111 bits are fixed to “0”, and the information polynomial becomes one with the lack of those terms of corresponding degrees. Depending upon which degree numbers are selected as the 111 terms with such “0” fixed coefficients from the information polynomial f(x) having 239 degrees, the computation amount of syndrome calculation becomes different, which is to be executed during decoding as described later. Therefore, this selection technique becomes important.

To generate check bits from the information polynomial f(x), as shown in the following Expression 4, data polynomial f(x)x¹⁶ will be divided by the code generation polynomial g(x) to obtain 15-degree remainder polynomial r(x).

f(x)x¹⁶=q(x)g(x)+r(x)

r(x)=b₁₅x¹⁵+b₁₄x¹⁴+ . . . +b₁x+b₀ [Exp. 4]

Use the coefficients b₁₅ to b₀ of this remainder polynomial r(x) as the check bits. In other words, 128 coefficients aᵢ₍₁₂₈₎ to aᵢ₍₁₎ selected from 239 ones serve as “information bits” while 16 bits from b₁₅ to b₀ serve as “check bits”, thereby resulting in that a total of 144 bits become “data bits” to be stored in the memory as shown in the following Expression 5.

aᵢ₍₁₂₈₎aᵢ₍₁₂₇₎ . . . aᵢ₍₃₎aᵢ₍₂₎aᵢ₍₁₎b₁₅b₁₄ . . . b₁b₀ [Exp. 5]

Here, aᵢ₍ₖ₎ is data to be externally written into the memory. Based on this data, check bit bⱼ is created in the built-in ECC system, and simultaneously written into the cell array.

### (Data Decoding in 2EC System)

Next, it will be explained a method of detecting errors from 144 bits read out data of the cell array and correcting up to 2-bit errors.

Supposing that errors take place when the memory stores the coefficients of 254-degree data polynomial f(x)x¹⁶, the errors also are represented by 254-degree polynomial. This error polynomial being e(x), the data read from the memory will be represented by a polynomial ν(x) with a structure shown in the following Expression 6.

ν(x)=f(x)x¹⁶+r(x)+e(x) [Exp. 6]

A term with coefficient “1” in the error polynomial e(x) is identical with an error. In other words, detecting e(x) is equivalent to performing error detection and correction.

What is to be done first is to divide the read out data polynomial ν(x) by the primitive polynomials m₁(x) and m₃(x) to obtain remainders, which are given as S₁(x) and S₃(X), respectively. As shown in the following Expression 7, it is apparent from the structure of ν(x) that the obtained remainders are equal to those of e(x) divided by m₁(x) and m₃(x), respectively.

$$ν ( x ) ≡ {S}_{1} ( x ) mod {m}_{1} ( x ) \to e ( x ) ≡ {S}_{1} ( x ) mod {m}_{1} ( x ) \\ ν ( x ) ≡ {S}_{3} ( x ) mod {m}_{3} ( x ) \to e ( x ) ≡ {S}_{3} ( x ) mod {m}_{3} ( x ) \qquad [ Exp . 7 ]$$

These remainder polynomials S₁(x) and S₃(x) are referred to as syndrome polynomials.

Assuming that 2-bit errors are present at i-th and j-th bits, e(x) will be expressed as follows: e(x)=xⁱ+x^{j}. These values “i” and “j” are obtainable by calculation of the index “n” of x=αⁿ, i.e., a root of m₁(x) that is an element in GF(256). More specifically, when letting a remainder, which is obtained by dividing xⁿ by m₁(x), be pⁿ(x), αⁿ=pⁿ(x). As shown in the following Expression 8, let αⁱ and α^{j} corresponding to error degrees be X₁ and X₂, respectively; let the indexes corresponding to S₁(α) and S₃(α³) with respect to syndromes S₁(x) and S₃(x) be σ₁ and σ₃, respectively; and let S₁(α) and S₃ (α³) be S₁ and S₃, respectively.

X₁=pⁱ(α)=αⁱ

X₂=p^{j}(α)=α^{j}

S₁ (α)=S₁=α^{σ1}

S₃(α³)=S₃=α^{σ3} [Exp. 8]

Since m₃(α³)=0, we obtain the following Expression 9.

S₁=X₁+X₃=e(α)

S₃=X₁³+X₃³=e(α³⁾ [Exp. 9]

At the second stage, considering polynomial Λ^{R}(x) with unknown quantities X₁ and X₂ as its roots, product X₁X₂ is represented by S₁ and S₃ as shown in Expression 10, so that the coefficients are calculable from the syndrome polynomials.

$$\begin{matrix}{S}_{3} / {S}_{1} = ( {X}_{1}^{3} + {X}_{2}^{3} ) / ( {X}_{1} + {X}_{2} ) \\ = {X}_{1}^{2} + {X}_{1} {X}_{2} + {X}_{2}^{2} \\ = {( {X}_{1} + {X}_{2} )}^{2} + {X}_{1} {X}_{2} \\ = {S}_{1}^{2} + {X}_{1} {X}_{2}\end{matrix} \\ {X}_{1} {X}_{2} = ( {S}_{3} + {S}_{1}^{3} ) / {S}_{1} \\ \begin{matrix}{Λ}^{R} ( x ) = ( x - {X}_{1} ) ( x - {X}_{2} ) \\ = {x}^{2} + {S}_{1} x + ( {S}_{3} + {S}_{1}^{3} ) / {S}_{1} \\ = {x}^{2} + {α}^{σ 1} x + {α}^{σ3 - σ1} + {α}^{2 σ1}\end{matrix} \qquad [ Exp . 10 ]$$

At the third stage, finding αⁿ, i.e., a root of Λ^{R}(x) in GF(256), it becomes possible to obtain the error bit locations “i” and “j” as “n” of αⁿ from X₁, X₂=αⁿ. In other words, searching Λ^{R}(x)=0 for n=0, 1, 2, . . . , 254, a hit number “n” will be specified as an error bit.

As shown in the following Expression 11, in case of a 1-bit error, we obtain X₁=S₁, X₁³=S₃=S₁³. Therefore, the error location is defined from S₁. If there are no errors, we obtain S₁=S₃=0. In case there are 3-bit or more errors and its position is incomputable, either one of S₁ and S₃ becomes 0, or there is no “n” as a solution.

(a) If 1-bit error, X₁=S₁ and X₁³=S₃=S₁³.

(b) If 0-bit error, S₁=S₃=0.

(c) If more than 3-bit errors, S₁ or S₃ is equal to 0, or there is no “n”. [Exp. 11]

### (Error Location Searching)

Error location searching is performed for obtaining the index “n” of root x=αⁿ satisfying Λ^{R}(x)=0. For this purpose, in this embodiment, change Λ^{R}(x) shown in Expression 10, and make possible to obtain “n” by use of only index relationships. In detail, using the variable conversion of: x=α^{σ1}y, to solve Λ^{R}(x)=0, and to obtain variable “y” shown in the following Expression 12, it becomes equal to each other.

y²+y+1+α^{σ3-3σ1}=0 [Exp. 12]

By use of this Expression 12, directly comparing the index obtained by variable calculation with that defined by syndrome calculation, it is possible to find a coincident variable. In detail, to solve the Expression 12, substitute αⁿ for “y” to obtain the index “yₙ” shown in Expression 13.

y²+y+1=α²ⁿ+α+1=α^{yn} [Exp. 13]

As shown in the following Expression 14, comparing the index σ₃-3σ₁ obtained by the syndrome calculation with the index “yₙ” obtained by the variable calculation, coincident “n” becomes the index of “y” corresponding to the error location.

σ₃−3σ₁≡yₙ mod 255 [Exp. 14]

To restore the index of variable “y” to that of the real variable “x”, as shown in Expression 15, multiply α^{σ1} into “y”.

x=α^{σ1} y=α^{σ1+n} [Exp. 15]

The index σ₁+n of α shown in Expression 15 is that of “x” corresponding to the error location, and this “x” will satisfy the error searching equation Λ^{R}(x)=0.

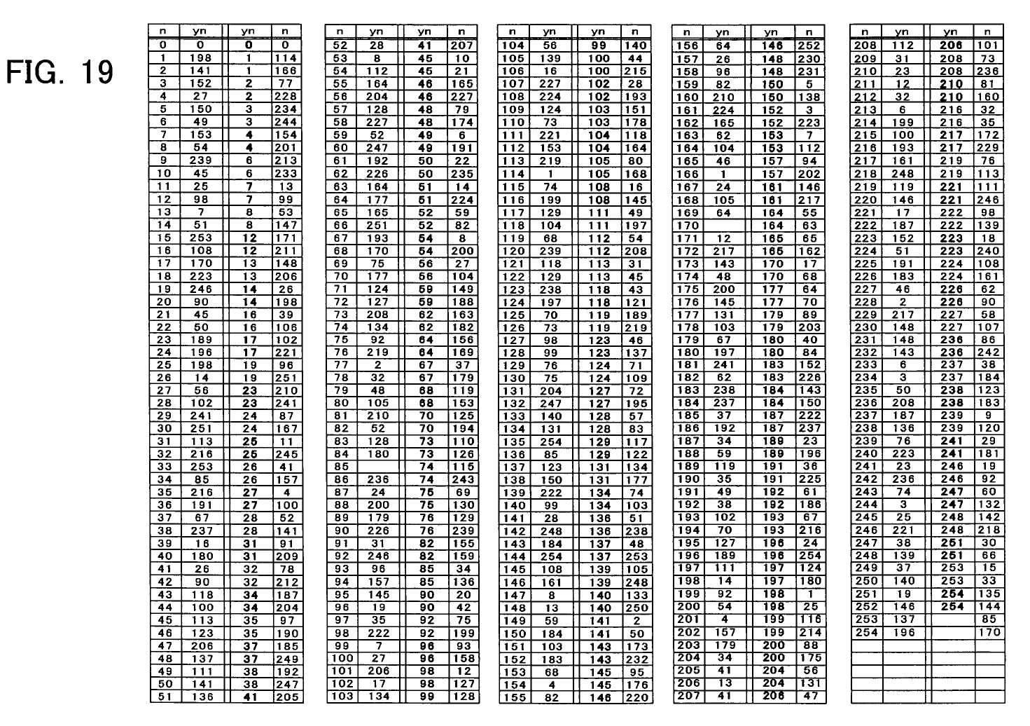

FIG. 19 shows a relationship between indexes “n” and “yₙ”There are two tables disposed in parallel as follows: one table, in which “yₙ” are arranged in order of “n”; and the other table, in which “n” are arranged in order of “yₙ”. The latter table shows that two “n”s correspond to one “yₙ” except in case of yₙ=0. Note that there is no “yₙ” corresponding to n=85 and 170 (these correspond to element 0 in Galois field). Further, it is shown that “yₙ” are not always present for the entire remainder of 255. In case there is no “yₙ”, it means that there is no solution in Λ^{R}(x)=0.

A calculation necessary for error location searching is to solve an index congruence. Actually, it is in need of solving congruences two times. Firstly, based on the syndrome index, obtain “yₙ” satisfying y²+y+1=α^{yn}. Next, after having found index “n” satisfying y=αⁿ in correspondence with “yₙ” obtain index “n” of “x” based on x=α^{σ1}y.

The congruences are formed in GF(256), i.e., of modulo 255. If directly executing this calculation as it is, it becomes equivalent to performing the comparison of 255×255, thereby resulting in that the circuit scale becomes large. In this embodiment, to make the calculation scale small, the calculation circuit will be divided into two parts, which are performed in parallel as follows.

That is, 255 is factorized into two prime factors, and each congruence is divided into two congruences. Then, it will be used such a rule that in case a number satisfies simultaneously the divided congruences, it also satisfies the original congruence. In this case, to make the circuit scale and calculation time as small as possible, it is preferred to make the difference between two prime factors as small as possible. In detail, using 255=17×15, two divided congruences are formed with modulo 17 and modulo 15.

First, to obtain “yₙ”, two congruences shown in Expression 16 are used. That is, an addition/subtraction between indexes with modulo 17 on condition that each term is multiplied by 15 and another addition/subtraction between indexes with modulo 15 on condition that each term is multiplied by 17 are performed simultaneously in parallel.

$$15 {y}_{n} ≡ 15 {σ}_{3} - 45 {σ}_{1} ( mod 17 ) \\ 17 {y}_{n} ≡ 17 {σ}_{3} - 51 {σ}_{1} ( mod 15 ) \to {y}_{n} ≡ {σ}_{3} - 3 {σ}_{1} ( mod 17 \cdot 15 ) \qquad [ Exp . 16 ]$$

Next, to obtain index “i”, two congruences shown in Expression 17 are used. That is, an addition/subtraction between indexes with modulo 17 on condition that each term is multiplied by 15 and another addition/subtraction between indexes with modulo 15 on condition that each term is multiplied by 17 are performed simultaneously in parallel.

$$15 i ≡ 15 n + 15 {σ}_{1} ( mod 17 ) \\ 17 i ≡ 17 n + 17 {σ}_{1} ( mod 15 ) \to i ≡ n + {σ}_{1} ( mod 17 \cdot 15 ) \qquad [ Exp . 17 ]$$

In FIG. 1, yₙ-locator 13a in the error location searching part 13 is for calculating two addition/subtractions shown in Expression 16 in parallel; and i-locator 13b is for calculating two addition/subtractions shown in Expression 17 in parallel.

Next, 1EC-2EW system (1-bit error correcting and 2-bit error warning) constructed in parallel together with the 2EC-BCH system will be explained below.

### (Data Encoding in 1EC System)

In 1EC system, 8-degree polynomial m₁(x), which is the same as in 2EC system, and 1-degree irreducible polynomial m₀(x)=x+1 with a root of α⁰=1, which is prime with m₁(x), will be used.

At an initial encoding step of generating check bits to be added to-be-written data, product polynomial h(x) of m₁(x)×m₀(x) is used as shown in Expression 18.

$$\begin{matrix}h ( x ) = {m}_{1} ( x ) {m}_{0} ( x ) \\ = {x}^{9} + {x}^{8} + {x}^{5} + {x}^{2} + x + 1\end{matrix} \qquad [ Exp . 18 ]$$

A maximum number of usable bits being 239, and coefficients of bit positions 16 to 254 being a₁₆ to a₂₅₄, a 238-degree information polynomial f(x) is represented as shown in Expression 19.

f(x)=a₂₅₄x²³⁸+a₂₅₃x²³⁷+ . . . +a₁₈x²+a₁₇x+a₁₆ [Exp. 19]

Supposing that actually used are 128 bits in 239 bits as described above, coefficients corresponding to the remaining 111 bits are fixed to “0”. To generate check bits from the information polynomial f(x), as shown in the following Expression 20, data polynomial f(x)x¹⁶ will be divided by the polynomial h(x) to obtain 8-degree remainder polynomial t(x). Coefficient c₈ to c₀ of the polynomial t(x) are used as check bits.

f(x)x¹⁶=q(x)h(x)+t(x)

t(x)=c₈x⁸+c₇x⁷+ . . . +c₁x+c₀ [Exp. 20]

In other words, 128 coefficients aᵢ₍₁₄₃₎ to aᵢ₍₁₆₎ selected from 239 and 9-bit of c₈ to c₀, a total of 137 bits become data to be stored in the memory as shown in the following Expression 21. aᵢ₍ₖ₎ is data externally written into the memory, and check bits cⱼ is generated based on the to-be-written data and stored together with the to-be-written data.

aᵢ₍₁₄₃₎aᵢ₍₁₄₂₎ . . . aᵢ₍₁₆₎(b₁₅b₁₄ . . . b₉)c₈c₇ . . . c₁c₀ [Exp. 21]

As shown in Expression 21, in the 1EC system, b₁₅ to b₉ in the check bits used in the 2EC system are fixed to “0”, a total of 128+9 bits are stored in the memory. In other words, the fixed bits of b₁₅ to b₉ are not written into the memory, so that the check bit area will be reduced to be about a half of that in the 2EC system.

### (Data Decoding in 1EC System)

Supposing that errors take place when the memory stores the coefficients of 254-degree data polynomial f(x)x¹⁶, the errors also are represented by 254-degree polynomial. This error polynomial being e(x), the data read from the memory may be represented by a polynomial ξ(x) with a structure shown in the following Expression 22.

ξ(x)=f(x)x¹⁶+t(x)+e(x) [Exp. 22]

Detecting degrees in the error polynomial e(x) is equivalent to performing error detection and correction.

As shown in the following Expression 23, what is to be done first is to divide the read out data polynomial ξ(x) by the primitive polynomials m₁(x) and m₀(x) to obtain remainders S₁(x) and “parity”, respectively.

$$ξ ( x ) ≡ {S}_{1} ( x ) mod {m}_{1} ( x ) \to e ( x ) ≡ {S}_{1} ( x ) mod {m}_{1} ( x ) \\ ξ ( x ) ≡ parity mod {m}_{3} ( x ) \to e ( x ) ≡ parity mod {m}_{3} ( x ) \qquad [ Exp . 23 ]$$

Assuming that 1-bit error polynomial is expressed as: e(x)=xⁱ, the error location “i” is obtainable by calculation of the index “n” of x=αⁿ, i.e., a root of m₁(x) that is an element in GF(256). When letting a remainder, which is obtained by dividing xⁿ by m₁(x), be pⁿ(x), αⁿ=pⁿ(x). As shown in the following Expression 24, letting αⁱ corresponding to error degree be X₁; letting the index corresponding to S₁(α) with respect to syndromes S₁(x) be σ₁ and σ₃; and letting S₁(α) be S₁, the relationship of: S₁=X₁, and parity=e(1)=1.

x₁=pⁱ(α)=αⁱ

S₁ (α)=S₁=α^{σ1}

X₁=e(α)=S₁

parity=e(1)=1 [Exp. 24]

“parity” becomes zero when e(x) contains even number of terms including zero. Particularly in case of 2-bit errors, parity=1+1=0.

At the second stage, solve X₁=S₁ with respect to the index. This is for searching “n” satisfying the congruence n≡σ₁ (mod 255), and detected n=i becomes error bit.

With respect to this error location searching, the 2EC system may be used as it is. Therefore, 255 is divided into the prime factors 17 and 15, and searching index satisfying two congruences shown in the following Expression 25.

$$15 i ≡ 15 {σ}_{1} ( mod 17 ) \\ 17 i ≡ 17 {σ}_{1} ( mod 15 ) \to i ≡ {σ}_{1} ( mod 17 \cdot 15 ) \qquad [ Exp . 25 ]$$

This method is the same as that in the 2EC system, and i-locator 13b in the error location searching part 13 shown in FIG. 1 performs this calculation. Although there is no need of calculating the sum of indexes, this is performed as calculation for adding zero to index.

The judgment of the calculating result will be represented in the following Expression 26.

(1) in case of 0-error, S₁=parity=0

(2) in case of 1-error, “i” is obtained from S₁, and parity=1

(3) in case of 2-errors, “i” is obtained from S₁, and parity=0

(4) in case of more than 3-bit errors, error detection is impossible. [Exp. 26]

So far, outlines of the 2EC system and 1EC system used together with the 2EC system have been explained. Next, these systems, calculation methods thereof and method of exchanging the 2EC system and 1EC system will be explained in detail.

In the system of this embodiment, in which all information bit, 239 bits, is not used, the selection of non-used bits will determine the calculation amount of the syndrome calculation. In the decoding step, after syndrome polynomial calculation, error location searching operation is performed. Therefore, to make the calculation time short, it is preferred to make the calculation amount small. This will be achieved in such a way as to select most suitable 128 terms (degrees) from the information polynomial.

Syndrome polynomial operations are performed simultaneously in parallel. Coefficient calculation of each degree of each polynomial is parity check of “1”. Thus, the total calculation amount is expected to be decreased if the coefficient of every degree is calculated without appreciable variations within almost the same time length.

One preferred selection method thereof is arranged to include the steps of: obtaining, for each “n”, a total sum of coefficient “1” for the syndrome calculation-use 7-degree remainder polynomials pⁿ(x) and p³ⁿ(x); and selecting a specific number of “n”s corresponding to the required data bit number from the least side in number of the total sum. Since, in the 2EC system, the first sixteen ones, i.e., the coefficients of x⁰ to x¹⁵ are used as check bits, 128 terms from the seventeenth one will be selected by ascending-order selection of a total sum of “1”s of the coefficients.

Additionally, upon completion of the selection within a group of the same total-sum numbers, selection is done in order from the overlap of “1”s being less at the same degree terms as the reference while specifying “n”s as a reference with the coefficients “1” being uniformly distributed between respective degree terms within pⁿ(x) and p³ⁿ(x) and the letting these “n”s be the reference. In other words, selection is done in order from the least side of the total sum of coefficients in the same terms as that of the reference with coefficients “1” of pⁿ(x), p³ⁿ(x).

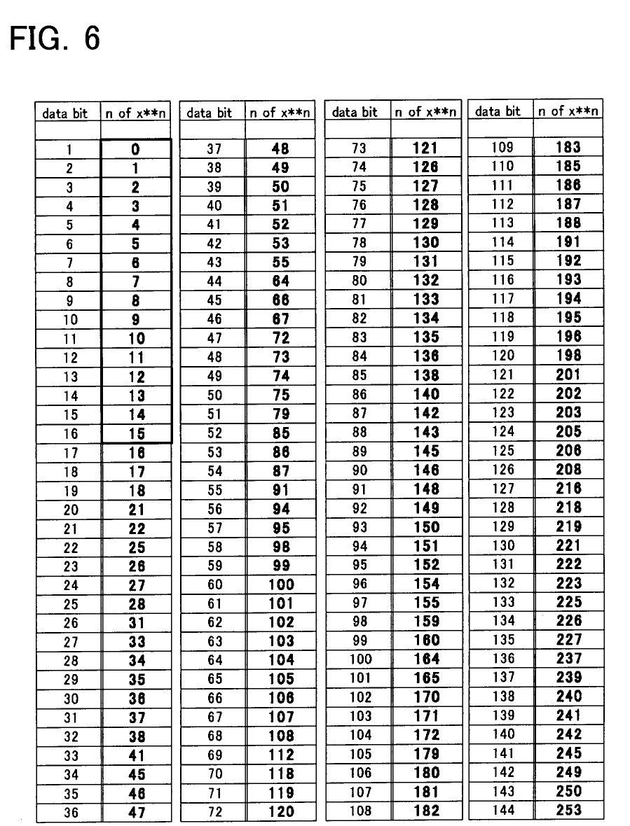

FIG. 6 shows 144 degrees “n” for use in the case of 144-bit data selected from 254 degrees in data polynomial f(x)x¹⁶ as described above.

Although this selection method does not minimize the greatest one of the number of the coefficients “1” of respective degrees of the polynomial for execution parity checking, it is still a simple method capable of reducing a step number of syndrome calculation while at the same time reducing the scale of syndrome calculation circuit without requiring large-scale calculation step-minimized one from among all possible combinations.

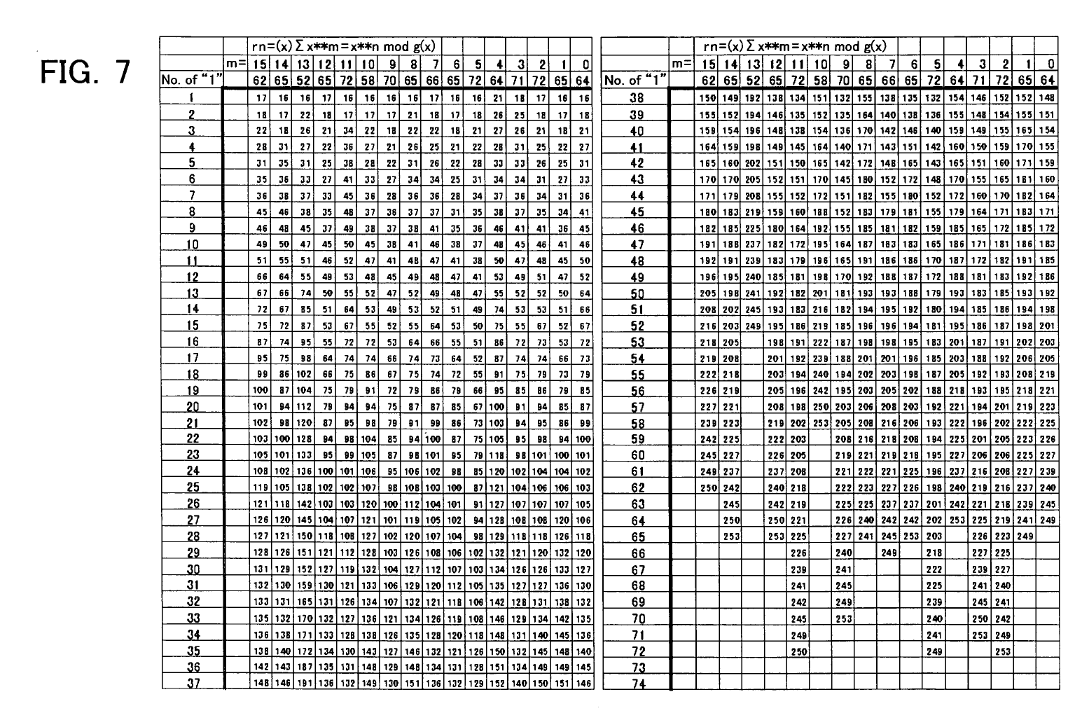

FIG. 7 is a coefficient table of the remainder polynomial rⁿ(x) obtained by g(x) in the 2EC system, i.e., a table of degree number “n”, at which the coefficient of the remainder polynomial rⁿ(x) for selected xⁿ is “1”.

For example, the degree number “n” of rⁿ(x) with the coefficient of x¹⁵ being “1” is 17, 18, 22, . . . , 245, 249 and 250 written in fields defined by the number of coefficient “1” being 1 to 62, in the column of m=15. b₁₅, which is equivalent to the coefficient of a check bit x¹⁵, will be obtainable as a result of parity check of this selected n-degree terms' coefficients in the information data polynomial f(x)x¹⁶.

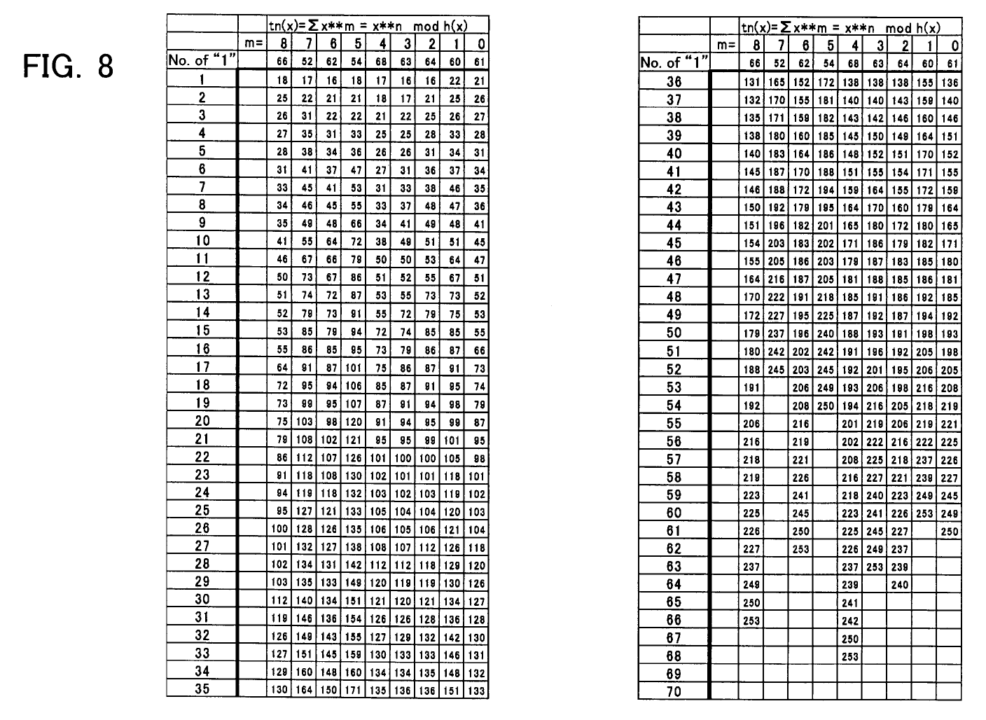

FIG. 8 is a coefficient table of the remainder polynomial tⁿ(x) obtained by the code generating polynomial h(x) in the 1EC system, i.e., a table of degree number “n”, at which the coefficient of the remainder polynomial tⁿ(x) for selected xⁿ is “1”.

For example, the degree number “n” of tⁿ(x) with the coefficient of x⁸ being “1” is 18, 25, 26, . . . , 237, 249, 250 and 253 written in fields defined by the number of coefficient “1” being 1 to 66, in the column of m=8.

c₈, which is equivalent to the coefficient of a check bit x⁸, will be obtainable as a result of parity check of this selected n-degree terms' coefficients in the information data polynomial f(x)x¹⁶.

In this embodiment, in the encoding part 11, input nodes of the parity check circuits for generating check bits are exchanged in accordance with the g(x) remainder table shown in FIG. 7 and the h(x) remainder table shown in FIG. 8.

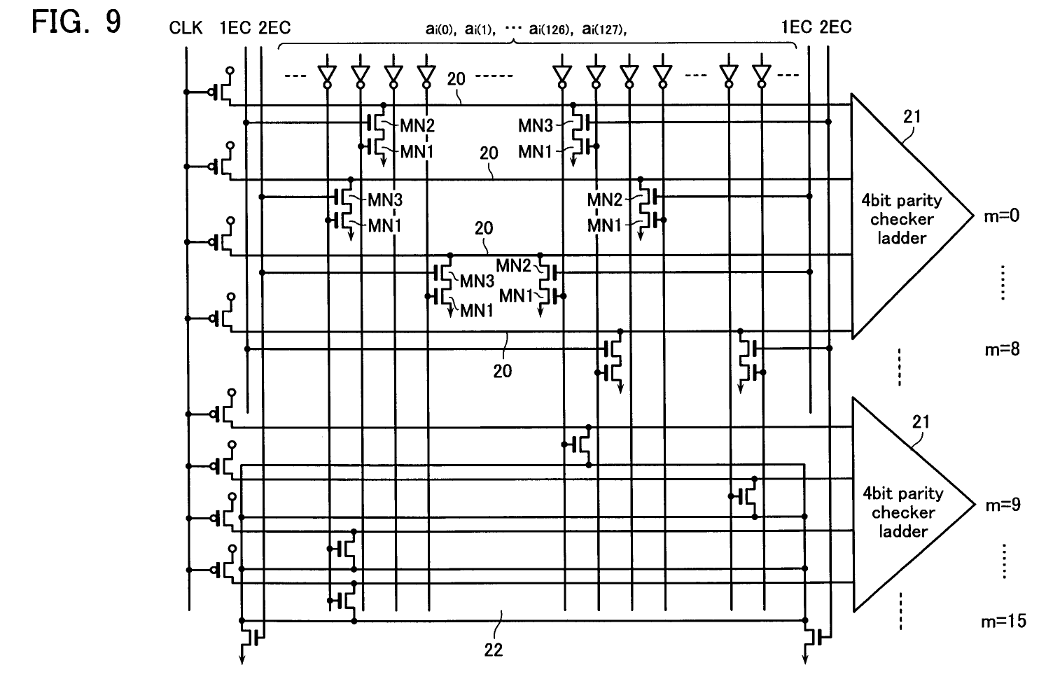

FIG. 9 shows parity checker ladders (PCLs) 21 and an input circuit 22 for these PCLs, which are used for generating check bits from the data polynomial f(x)x¹⁶ as the remainder of g(x) or h(x).

“1EC” is a mode selection signal, which becomes “H” in case of 1EC system using the code generation polynomial h(x) while “2EC” is another mode selection signal, which becomes “H” in case of 2EC system using the code generation polynomial g(x).

Each of sixteen 4-bit PCLs 21 is formed of a set of XOR circuits for calculating the value of each degree of the corresponding polynomial to generate check bits, and calculates parity of inputs selected in accordance with the corresponding remainder table of xⁿ by the corresponding code generation polynomial.

The input circuit 22 has precharge nodes 20, which are precharged by clock CLK, and discharge-use transistors MN1, which are for discharging the nodes 20. Input to the gates of these transistors MN1 are inverted ones of 128 coefficient signals aᵢ₍₀₎ to aᵢ₍₁₂₇₎, which correspond to-be-written data. What coefficient is to be selected as a discharging signal will be determined by which of 2EC system and 1EC system is selected. Therefore, transistors MN3 (or MN2) are disposed between the discharge transistors MN1 and precharge nodes 20, which are selectively activated by the mode selection signal 2EC (or 1EC).

In case of the 2EC system, the check bit polynomial is of 15-degree while in case of the 1EC system, it is of 8-degree. Therefore, 4-bit PCLs from m=0 to m=8 are shared by the 1EC and 2EC systems. In this range, input signals are switched by the mode selection signals 1EC and 2EC. In other words, in this rage, the input circuit 22 for parity check circuits will be exchanged in configuration with 1EC and 2EC.

4-bit PCLs from m=9 to m=15 become active only in case of 2EC system. Therefore, in this range, the input circuit 22 is set in an input-fixed state, i.e., kept in the precharged state in case of 1EC system.

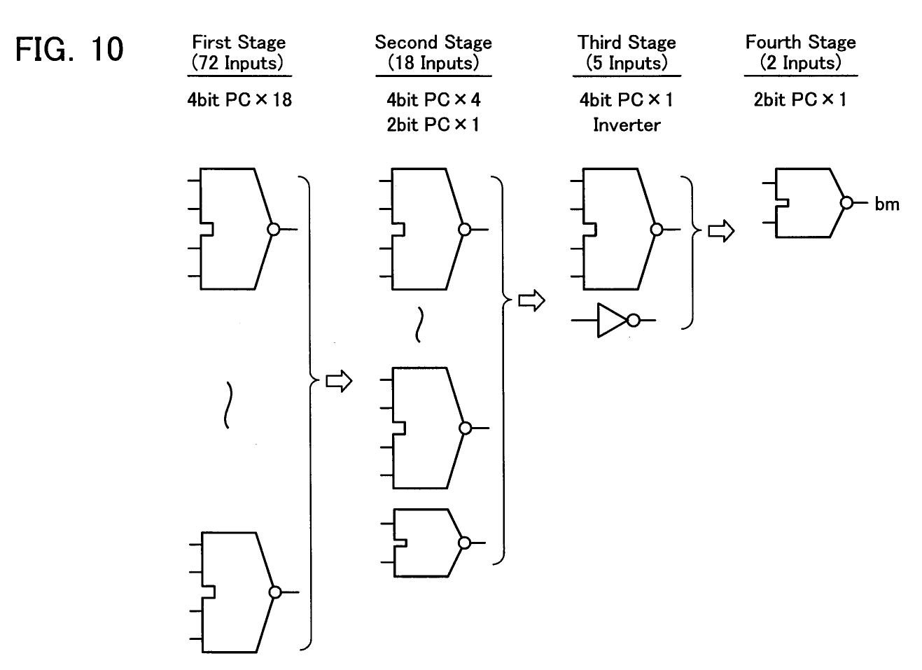

FIG. 10 shows an example of the 4-bit PCL 21. The basic configuration is for 2EC system. The first stage inputs are exchanged between the 2EC system and the 1EC system with the switching circuit explained with reference to FIG. 9. In case of 2EC system, the maximum value of parity check bits is 72 at m=11, 5 and 2 as shown in FIG. 7. In FIG. 10, such a case is shown as an example. For each degree “m”, “n”s are selected from the table shown in FIG. 7, and parity check of the coefficients an is performed.

A proper combination of parity checkers (PCs) used is determined depending on the number of inputs belonging to which one of the division remainder systems of 4. More specifically, if it is just dividable by 4, only 4-bit PCs are used; if the division results in presence of a remainder 1, 2-bit PC, one input of which is applied with Vdd, i.e., an inverter, is added; if the remainder is 2, 2-bit PC is added; and if 3 remains then 4-bit PC, one input of which is applied with Vdd, is added.

In the example of m=11, 5 and 2, there are 72 inputs. So in this case, four stages of PCs are used as follows: the first stage is formed of eighteen 4-bit PCs; the second stage is formed of four 4-bit PCs and one 2-bit PC because of 18 inputs; the third stage is formed of one 4-bit PC and an inverter because of 5 inputs; and the fourth stage is formed of one 2-bit PC because of 2 inputs.

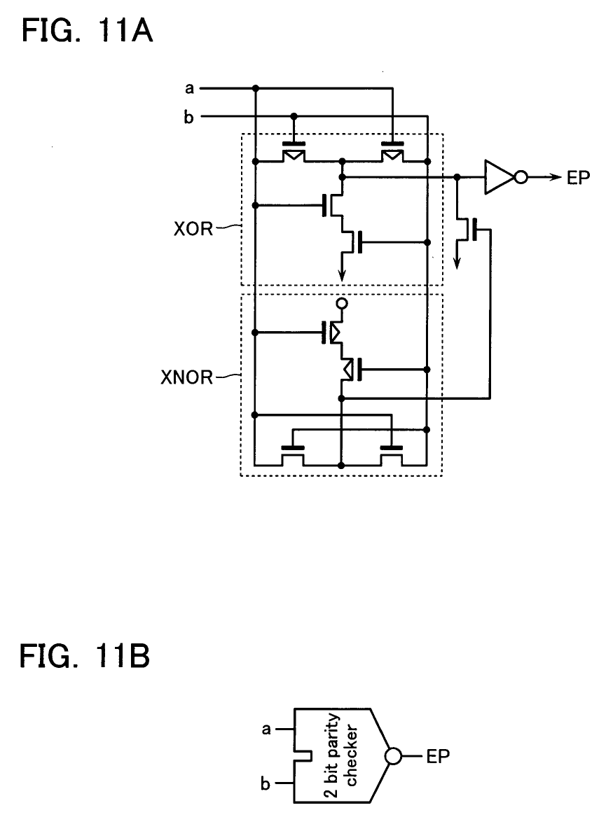

FIGS. 11A and 11B show a 2-bit parity check (PC) circuit and the circuit symbol. This PC circuit has an XOR circuit and an XNOR circuit for performing a logic operation for input signals “a” and “b” to output “1” (even-parity) to the output node EP when the number of “1”s in the input signals is even.

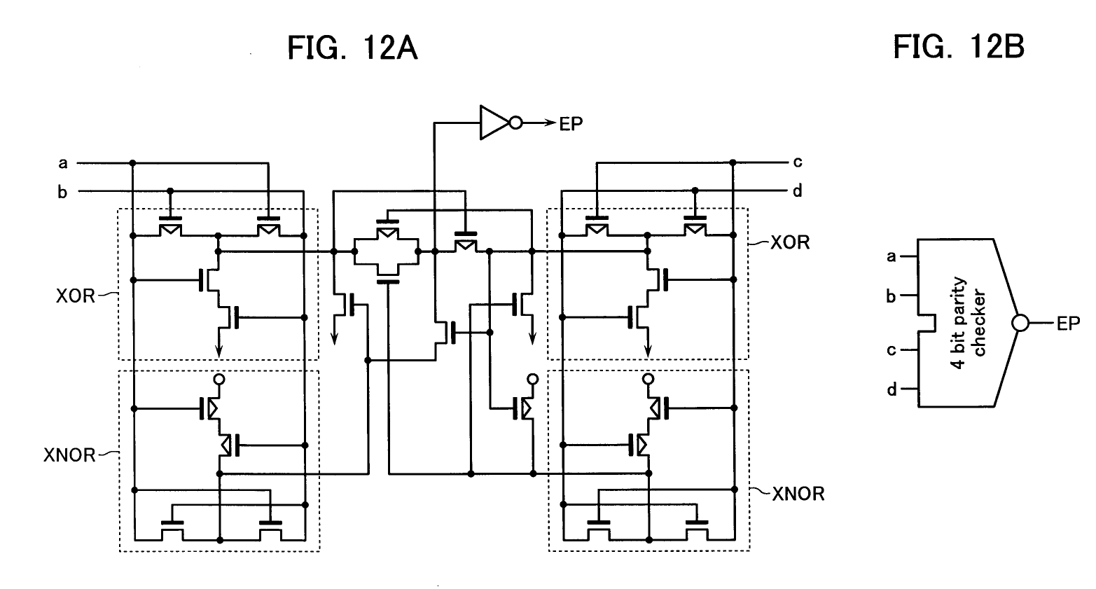

FIGS. 12A and 12B show a 4-bit parity check (PC) circuit and the circuit symbol. This PC circuit has two XOR circuits and two XNOR circuits for performing a logic operation for input signals “a”, “b”, “c” and “d” to output “1” to the output node EP when the number of “1”s in the input signals is even.

Next, the syndrome operation part 12 for decoding the read out data for error detecting will be explained below.

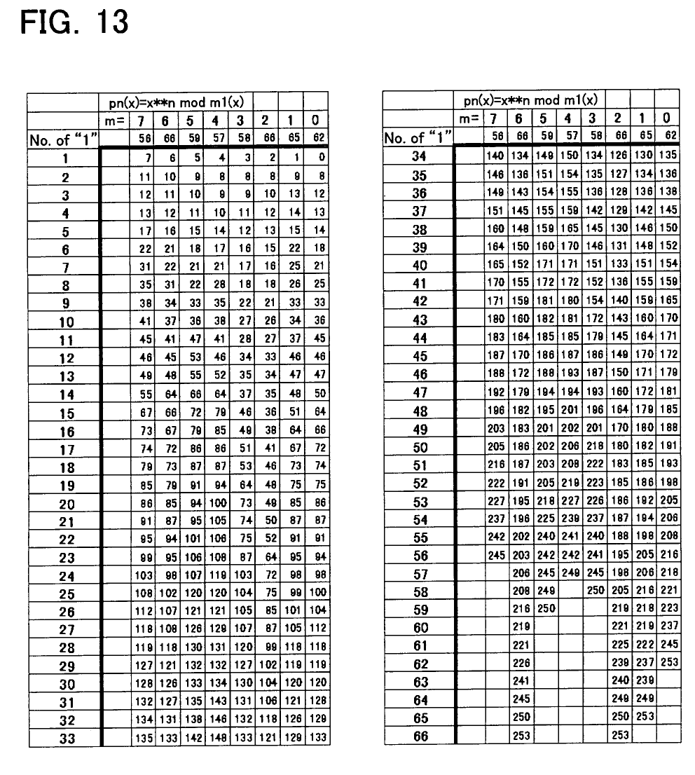

FIG. 13 is a table of the number of degrees whose coefficient is “1” in 7-degree remainder polynomial pⁿ(x) for use in the calculation of the syndrome polynomial S₁(x). For example, the degree number of “n” of pⁿ(x) with the coefficient x⁷ being “1” is 7, 11, 12, . . . , 237, 242 and 245 written in fields defined by the number of coefficient “1” being from 1 to 56, in the column of m=7. The coefficient of x⁷ of S₁(X) is obtained as a result of parity check of the coefficients of this selected n-degree terms in the data polynomial ν(x).

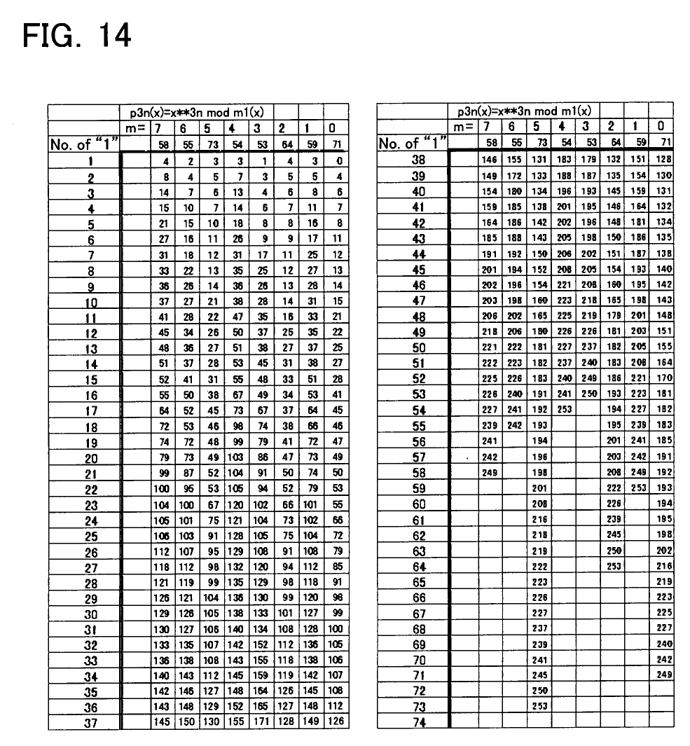

FIG. 14 is a table of the number of degrees whose coefficient is “1” in 7-degree remainder polynomial p³ⁿ(x) for use in the calculation of the syndrome polynomial S₃(x). For example, the degree number of “n” of p³ⁿ(x) with the coefficient x⁷ being “1” is 4, 8, 14, . . . , 241, 242 and 249 written in fields defined by the number of coefficient “1” being from 1 to 58, in the column of m=7. The coefficient of x⁷ of S₃(X) is obtained as a result of parity check of the coefficients of this selected n-degree terms in the data polynomial ν(x).

Since, in case of 1EC, parity check is performed for 128+9 bits, it is in need of preparing PCLs with the inputs equal to the data bits. As apparent from FIG. 14, inputs at m=2 and m=5 are 64 and 73, respectively, and the sum becomes a desired value of 137. So, in case of 1EC, parity check is performed with 4-bit PCLs with the above-described inputs.

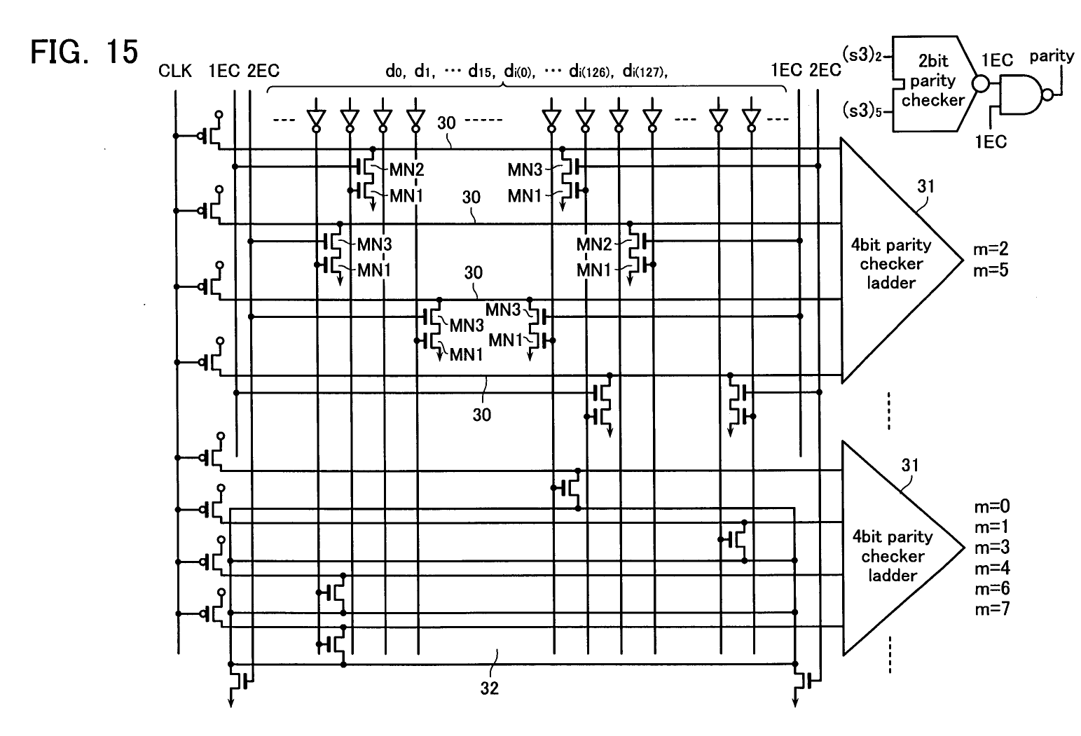

FIG. 15 shows an example of a parity checker ladder (PCL) 31 and the input circuit 32 used in the syndrome operation part 21 shown in FIG. 1. As described above, m=2 and m=5 are used in the 1EC system. Therefore, PCLs 31 at m=2 and m=5 are shared by the 2EC system and 1EC system; and the remaining PCLs are used only in the 2EC system.

The input circuit 32 of the PCL 31 is basically the same as the check bit generation part shown in FIG. 9, and has precharge nodes 30, which are precharged by clock CLK, and discharge-use transistors MN1, which are for discharging the nodes 30. Input to the gates of these transistors MN1 are inverted ones of data d₀ to d₁₅ and dᵢ₍₀₎ to dᵢ₍₁₂₇₎. What coefficient is to be selected as a discharging signal will be determined by which of the 2EC system and 1EC system is selected. Therefore, transistors MN3 (or MN2) are disposed between the discharge transistors MN1 and precharge nodes 30, which are selectively activated by the mode selection signal 2EC (or 1EC).

It is PCLs at m=2 and m=5 that the input circuit configuration is changed in accordance with the mode select signal 1EC and 2EC. In case of 1EC, the PCL outputs (s3)₂ and (s3)₅ are further input to a 2-bit PC. The output of this 2-bit PC, which is inverted, is input to a NAND gate, which is activated by the mode select signal 1EC. As a result, parity output will be obtained only in the case of 1EC. In case of 2EC, parity=“1” is always obtained with the NAND gate.

In case of 1EC, inputs being fixed in potential, the remaining PCLs are made inactive. Further, since only 9 bits serve as check bits, dₚ to d₁₅ in the input data are set to be

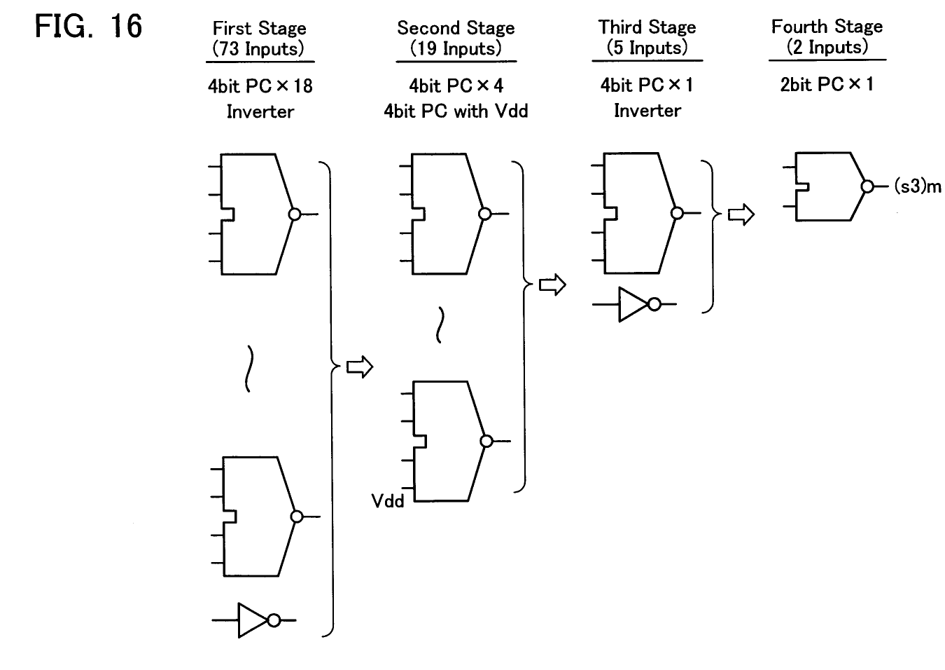

FIG. 16 shows a detailed example of the syndrome generating-use parity checker ladder (PCL) shown in FIG. 15, in the case of 2EC system.

As apparent from FIG. 14, the maximum number of parity check bits is 73 when m=5 of xₘ. Therefore, FIG. 16 shows an example with 73 inputs. Since such “n”s are shown in the table that coefficients of m-degree terms are not “0” in the remainder polynomial p³ⁿ(x), which is obtained by dividing x³ⁿ by m₁(x), select “n” for each “m” from the table, and perform parity check with dₙ.

There are 73 inputs in the example of m=5. Therefore, in this example, four stages of PCs are used as follows: the first stage is formed of eighteen 4-bit PCs and an inverter; the second stage is formed of four 4-bit PCs and one 4-bit PC with one input fixed at Vdd because there are 19 inputs; the third stage is formed of one 4-bit PC and an inverter because there are 5 inputs; and the fourth stage is formed of one 2-bit PC because there are 2 inputs. The output of the fourth stage serves as the syndrome coefficient (s3)ₘ.

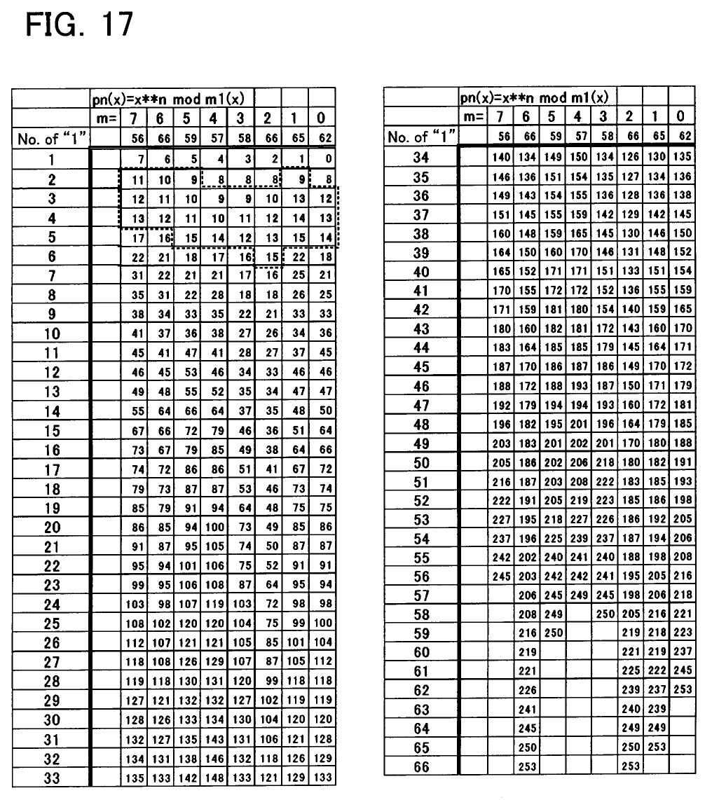

FIG. 17 is a table of the number of degrees whose coefficient is “1” in 7-degree remainder polynomial pⁿ(x) for use in the calculation of the syndrome polynomial S₁(x), which is the same as FIG. 13. Since, in case of 1EC, inputs from n=9 to n=15 in ν(x) are fixed to be “0”, the corresponding range in the table shown in FIG. 17, which is surrounded by a dotted line, is not used.

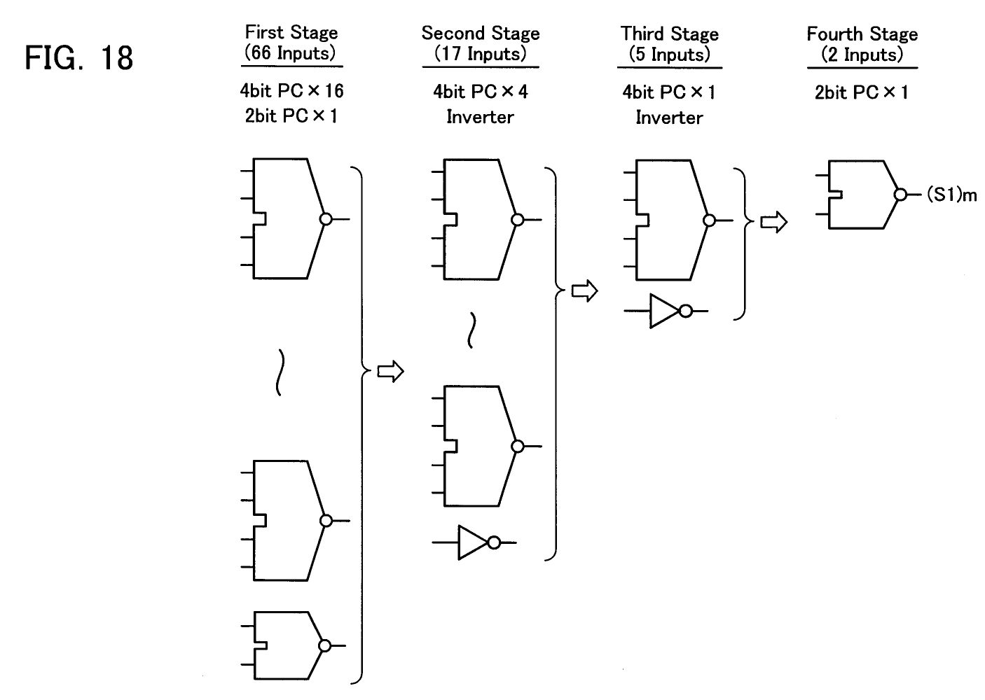

FIG. 18 shows a detailed example of a 4-bit PCL used in the calculation of the syndrome polynomial S₁(x). The maximum number of parity check bits is 66 when m=6, 2 of x^{m}. Therefore, FIG. 18 shows an example with 66 inputs. Select “n” for each “m” from the table, and perform parity check with dₙ. The calculation result serves as the syndrome coefficient (s1)ₘ.

A proper combination of parity checkers (PCs) used is determined depending on the number of inputs belonging to which one of the division remainder systems of 4. If it is just dividable by 4, only 4-bit PCs are used; if the division results in presence of a remainder 1, 2-bit PC, one input of which is applied with Vdd, i.e., an inverter, is added; if the remainder is 2, 2-bit PC is added; and if 3 remains then 4-bit PC, one input of which is applied with Vdd, is added.

In the example of m=6, 2, there are 66 inputs. Therefore, in this case, four stages of PCs are used as follows: the first stage is formed of sixteen 4-bit PCs and one 2-bit PC; the second stage is formed of four 4-bit PCs and one inverter because of 17 inputs; the third stage is formed of one 4-bit PC and an inverter because of 5 inputs; and the fourth stage is formed of one 2-bit PC because of 2 inputs.

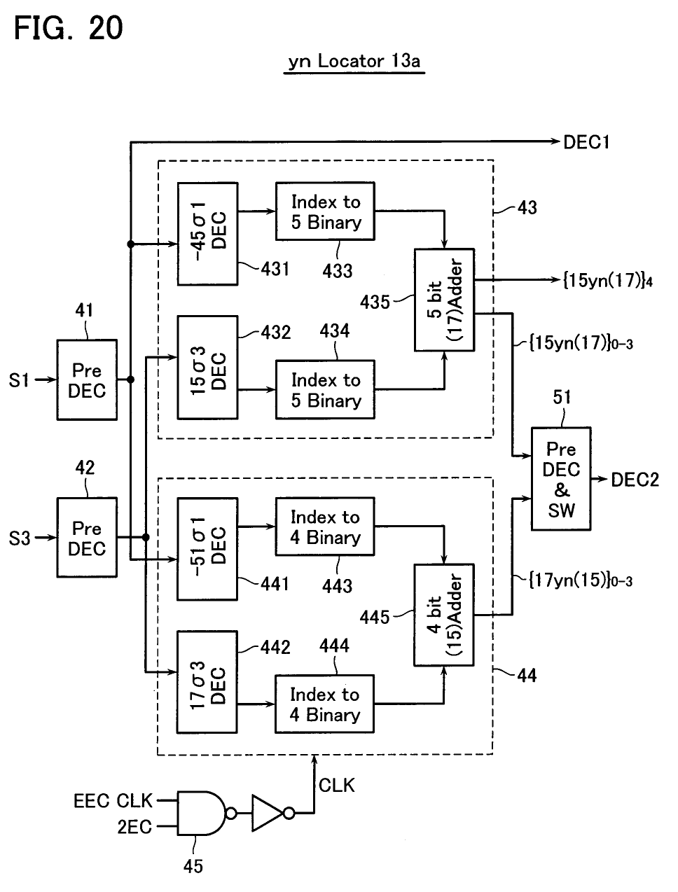

Next, error location searching part 13 for searching error locations based on the syndrome operation result and error correcting part 14 shown in FIG. 1 will be explained in detail with reference to FIGS. 20 to 22.

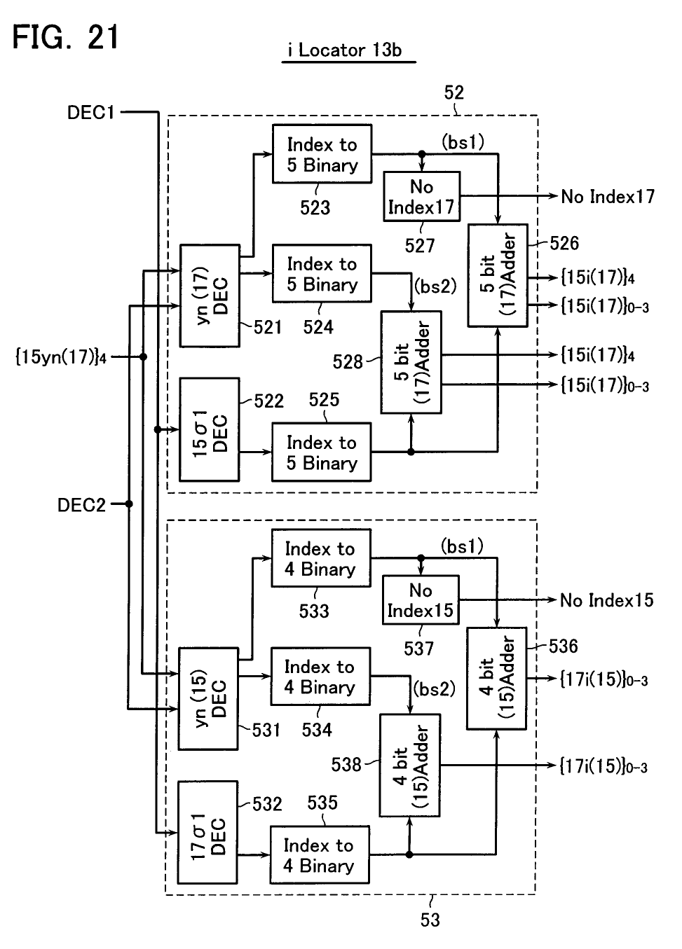

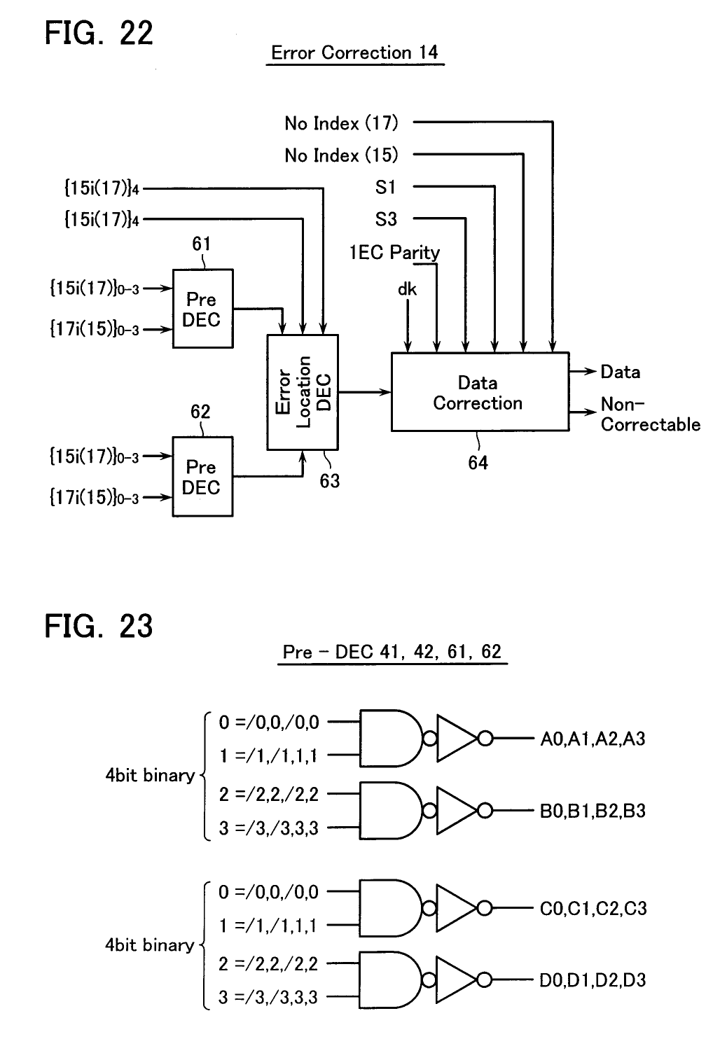

FIG. 20 shows the yₙ-locator 13a; FIG. 21 the i-locator 13b; and FIG. 22 the error correction circuit 14. Disposed at the input node of each circuit is a pre-decode circuit for making the circuit scale small.

The yₙ-locator 13a has, as shown in FIG. 20, pre-decoders 41 and 42, which decode the syndromes S₁ and S₃, respectively; and index adder part 43 with modulo 17 and index adder part 44 with modulo 15, which perform addition operations for the decoded outputs. These index adder parts 43 and 44 are for solving two congruences shown in Expression 16, i.e., calculation parts for calculating two error indexes yₙ in the case of 2EC.

These adder parts 43 and 44 are activated by NAND gate 45 only when the mode select signal 2EC is “H”, and kept inactive in case of 1EC without receiving ECC clock.

The index adder part 43 has: −45σ₁ decoding part 431 and 15σ₃ decoding part 432 for decoding the respective pre-decoded syndromes and converting them to indexes; index/binary converting part 433 and 434, which convert the respective indexes to binary data; and 5-bit adder(mod 17) 435 for adding the obtained binary data with modulo 17.

The index adder part 44 has: −51σ₁ decoding part 441 and 17σ₃ decoding part 442 for decoding the respective pre-decoded syndromes and converting them to indexes; index/binary converting parts 443 and 444, which convert the respective indexes to binary data; and 4-bit adder(mod 15) 445 for adding the obtained binary data with modulo 15.

Pre-decoder & switch 51 is disposed for decoding the lower 4-bit {17yₙ(15)}₀₋₃ in the output of 5-bit adder 435 and the 4-bit output {15yₙ(17)}₀₋₃ of 4-bit adder 445. When yₙ-locator 13a is inactive, the pre-decoder & switch 51 serves to set the outputs of adder 435 and 445 to be “0”, and transfer it to i-locator 13b.

The i-locator 13b shown in FIG. 21 is for calculating the error location index “i”, which is shared by 1EC and 2EC as described above. In other words, this is for solving the two congruences shown in Expression 17 in parallel, and has index adder part 52 with modulo and index adder part 53 with modulo 15.

The index adder part 52 has: yₙ(17) decoding part 521 for decoding the output DEC2 of the pre-decoder 51 and the uppermost bit {15yₙ(17)}₄ of the 5-bit adder 435; 15σ₁ decoding part 522 for decoding the decode output of the syndrome S₁; index/binary converting parts 523, 524 and 525 disposed at outputs the decoding parts 521 and 522 to convert output indexes to binary data; and two 5-bit(17) adders 526 and 528, which add the binary data with modulo 17. Further disposed at the output of the index/binary converting part 523 is a detecting part 527 for detecting that the calculation is impossible (i.e., No-index 17).

As well as the index adder part 52, the index adder part 53 has: yₙ(15) decoding part 531; 17σ₁ decoding part 532; index/binary converting parts 533, 534 and 535 disposed at outputs the decoding parts 531 and 532; and two 4-bit(15) adders 536 and 538. Further disposed at the output of the index/binary converting part 533 is a detecting part 537 for detecting that the calculation is impossible (i.e., No-index 15).

The error correction part 14 has, as shown in FIG. 22, pre-decoder 61 for pre-decoding the lower 4-bit outputs {15i(17)}₀₋₃ of the two 5-bit adders 526 and 528 in the i-locator 13b; and pre-decoder 62 for pre-decoding the 4-bit outputs {17i(15)}₀₋₃ of the two 4-bit adders 536 and 538 in the i-locator 13b. These pre-decoder outputs and the uppermost bit outputs of two 5-bit adders 526 and 528 are input to the error location decoding part 63.

The output of the error decoding part 63 designates the error location. Read out data dₖ of the memory core is input to data correction circuit 64 and inverted (i.e., corrected) at the error location to be output. Further input to the data correction circuit 64 are non-calculable signals “No index(17)”, “No index(15)”, syndromes S₁ and S₃, and 1EC parity, which make it possible to output Non-correctable signal.

The pre-decoders 41, 42, 61 and 62 each is for converting 256 binary signal data states defined by 8 bits to a combination of Ai, Bi, Ci and Di (i=0 to 3), which is formed of NAND circuits as shown in FIG. 23. That is, 8-bit binary data is divided by 2-bit to be expressed as 4-bit binary, and these are defined as Ai, Bi, Ci and Di. With these pre-decoders, it is possible to reduce the number of transistors used in the following decoder to be a half (i.e., 4 from 8).

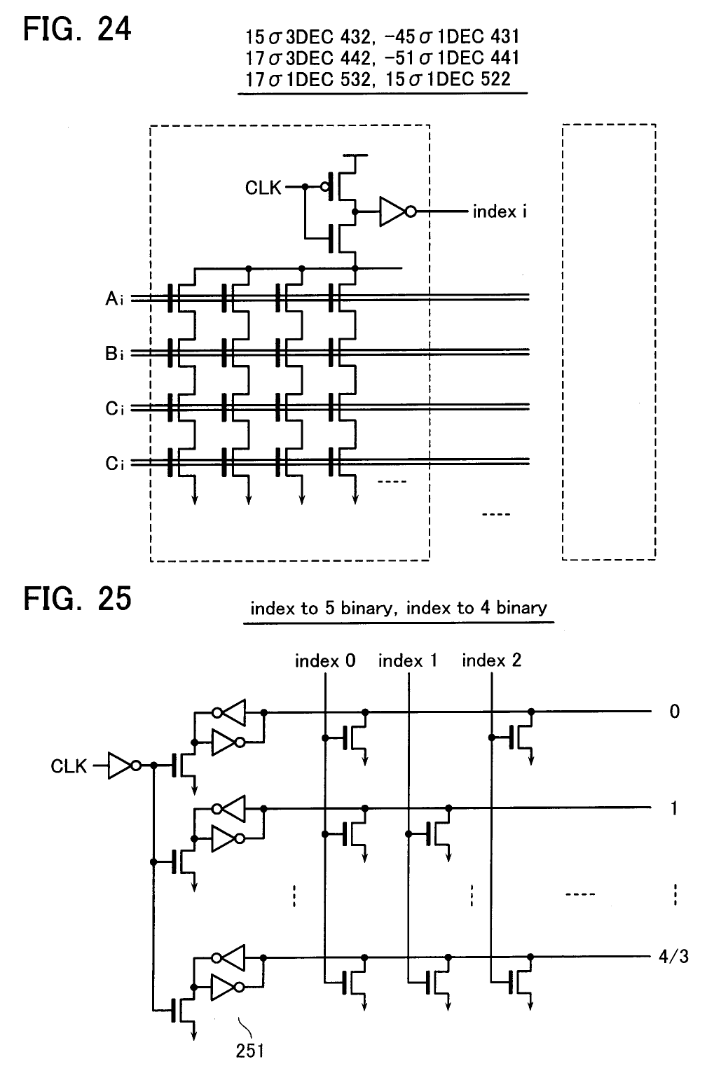

15σ₃ decoding part 432, −45σ₁ decoding part 431, 17σ₃ decoding part 442, −51σ₁ decoding part 441, 17σ₁ decoding part 532 and 15a, decoding part 522 are formed as shown in FIG. 24 with the same configuration except that inputs are different from each other. That is, the decoding part is formed of NAND circuits arranged in number of the irreducible polynomials belonging to the respective remainder classes, in each of which transistors are connected in series with the pre-decode outputs Ai-Di applied to gate thereof.

The decoding part has a common node, which is precharged by clock CLK, and outputs a remainder class index signal “index i” in accordance with whether the common node is discharged or not. Gate wirings corresponding to Ai, Bi, Ci and Di (i=0 to 3) are disposed to be selectively coupled to gates of the respective transistors in the NAND circuits in accordance with decoding codes.

Index/binary converting parts 433, 434, 443, 444, 523-525, 533-535 are for converting the remainder class index signals “index i” to binary data, and formed as shown in FIG. 25. To hold the converted binary data, latch circuits 251 are disposed, which are reset by clock CLK. In case that indexes are not input, all signal corresponding to binary number 31 is kept “H” in case of 5-binary while all signal corresponding to binary number 15 is kept “H” in case of 4-binary.

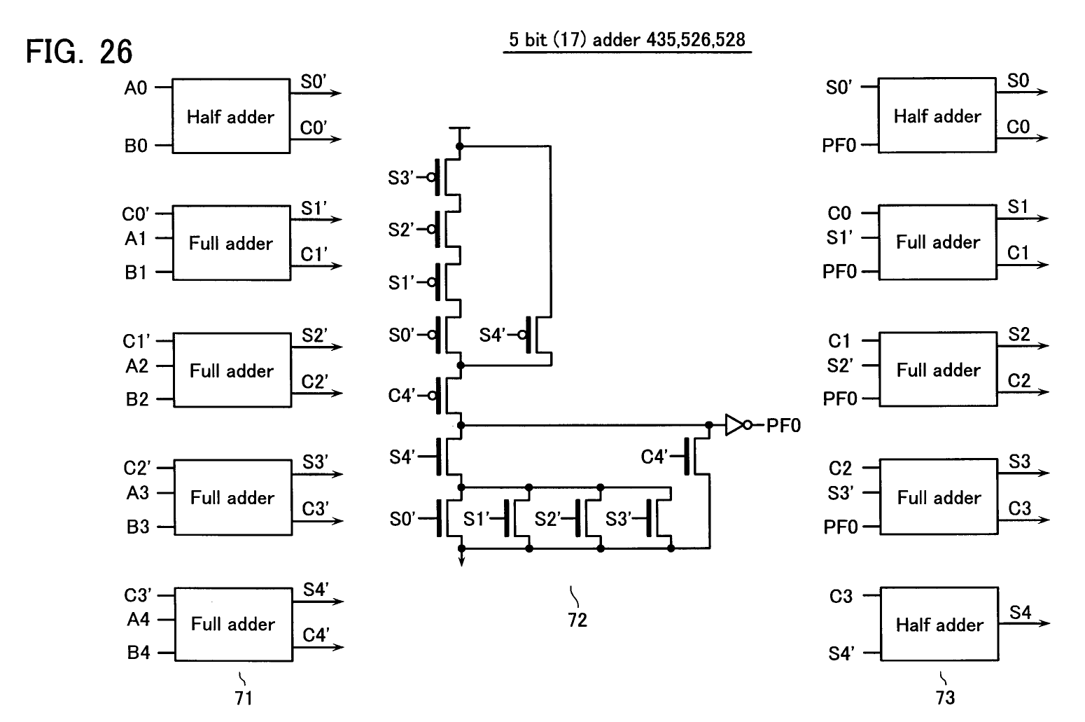

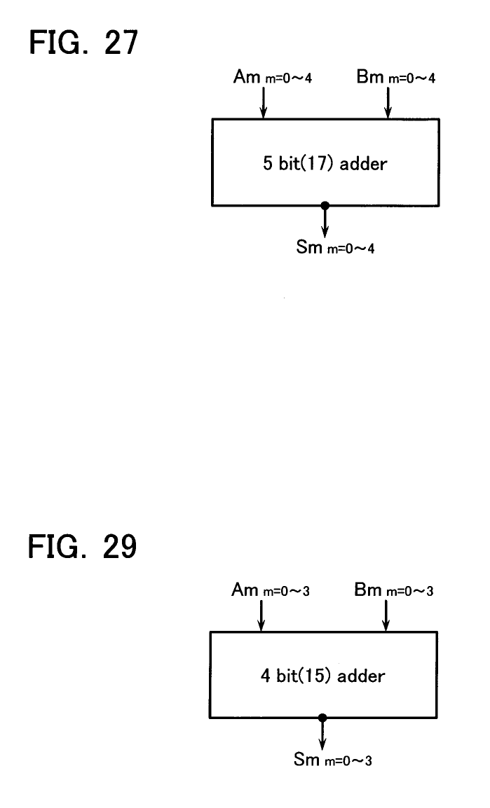

FIG. 26 shows an example of 5-bit adders(17) 435, 526 and 528, which obtain a sum as a remainder by modulo 17; and FIG. 27 shows the circuit symbol. As shown in FIG. 26, this adder has: a first stage adder circuit 71 for 5 bits; a carry correction circuit 72, which detects that the sum of the first stage adder circuit 71 is 17 or more and carry; and a second stage adder circuit 73, which adds a complement of the sum for 32 to it together with the carry correction circuit 72 when it is 17 or more. In detail, when the sum becomes 17, in the second stage adder circuit 73, complement 15(=32−17) is added to the sum.

The carry correction circuit 72 is for generating signal PF0 in accordance with the output state of the first stage adder circuit 71. Explaining in detail, it detects that the uppermost bit output S4′ of the first stage adder circuit 71 is “1” and at least one on the other bit outputs S0, S1′ to S3′ is “1” (i.e., the sum is 17 or more), and outputs PF0=“H”.

The second stage adder circuit 73 has such a logic that a complement (01111) of 17 is added to the sum of the first stage adder circuit 71 when it is 17.

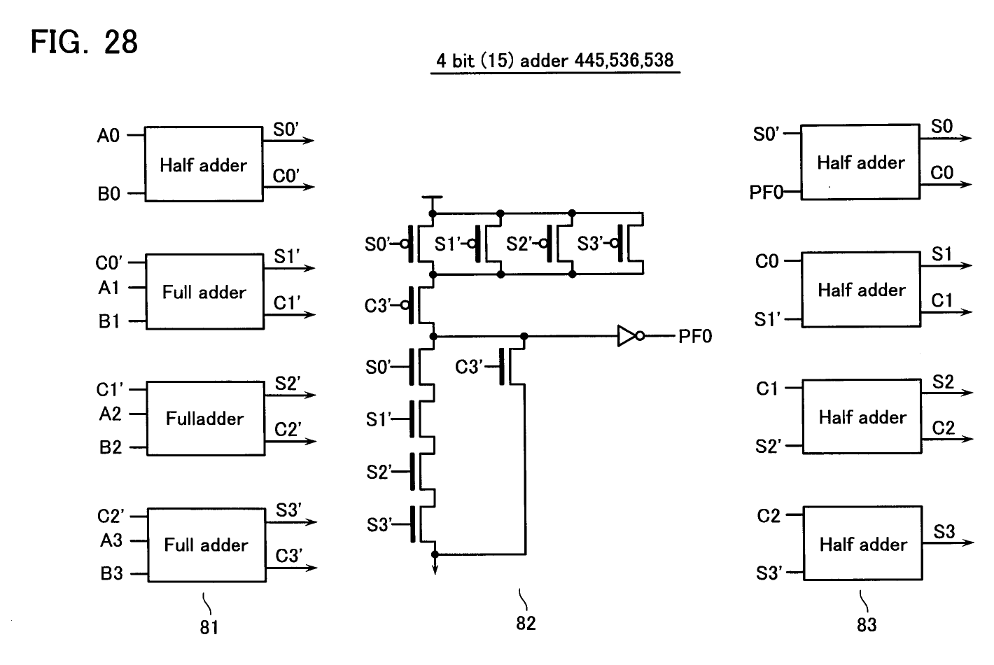

FIG. 28 shows an example of 4-bit adder(15) 445, 536 and 538, which obtain a sum as a remainder by modulo 15; and FIG. 29 shows the circuit symbol. This adder has: a first stage adder circuit 81 for 4 bits; a carry correction circuit 82, which detects that the sum of the first stage adder circuit 81 is 15 or more and carry; and a second stage adder circuit 83, which adds a complement of the sum for 16 to it together with the carry correction circuit 82 when it is 15 or more. In detail, when the sum becomes 15, in the second stage adder circuit 83, complement 1(=16−15) is added to the sum.

The carry correction circuit 82 is for generating signal PF0 in accordance with the output state of the first stage adder circuit 81. Explaining in detail, it detects that the outputs S0′ to S3′ of the first stage adder circuit 81 are “1” (i.e., the sum is 15 or more), and outputs PF0=“H”.

The second stage adder circuit 73 has such a logic that a complement (0001) of 15 is added to the sum of the first stage adder circuit 81 when it is 15.

It is not required of the adders shown in FIGS. 26 and 28 to be clock-synchronized, and when the input is determined, the output will be determined. As a result, the timing control of the system may be reduced in workload.

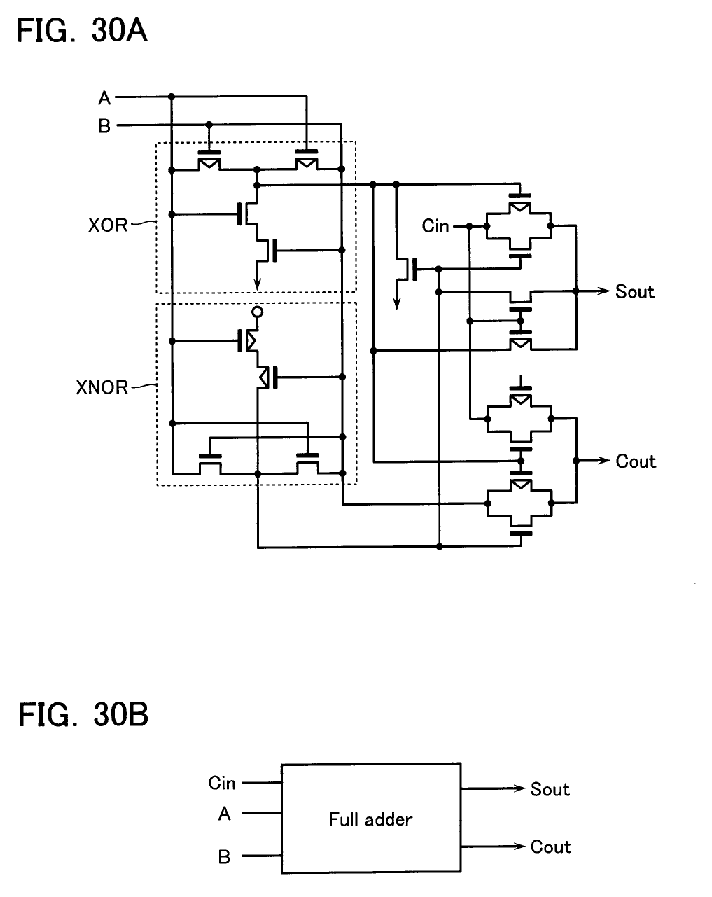

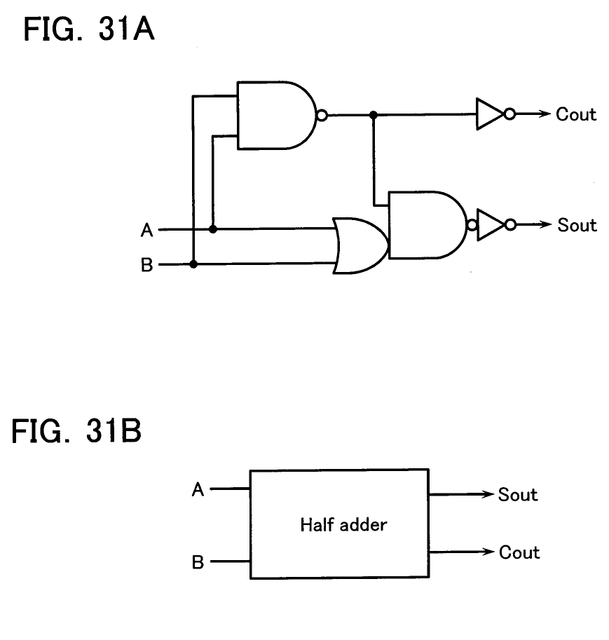

The Half adder and full adder used in the adders shown in FIGS. 26 and 28 are sown in FIGS. 30A, 30B and FIGS. 31A, 31B, respectively. The full adder is configured to perform a logic operation for to-be-added signals A, B and a carry signal Cin with XOR circuit and XNOR circuit to output a sum Sout and a carry signal Cout. The half adder is formed of usual logic gates.

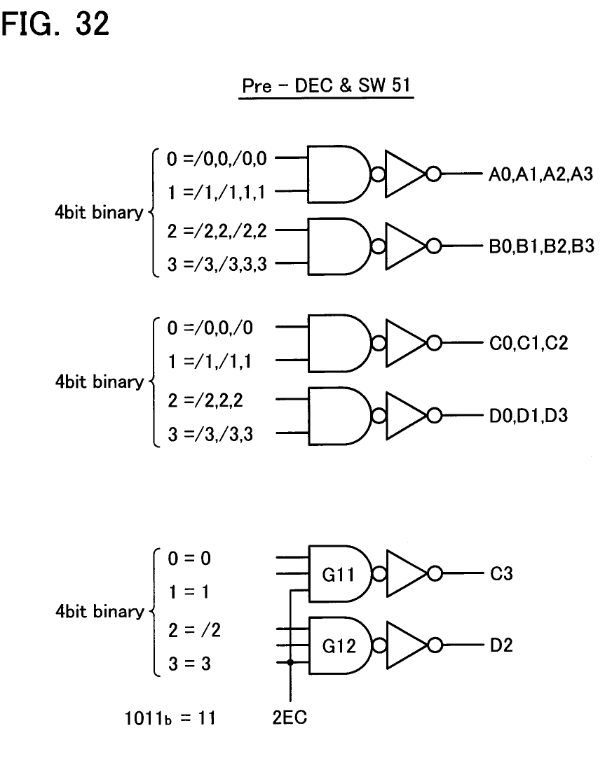

FIG. 32 shows the pre-decoder & switch 51 disposed at the output node of yₙ-locator 13a. This is for decoding the 4-bit outputs of 4-bit(15) adder and 5-bit outputs of 5-bit(17) adder, and is formed basically the same as the pre-decoder shown in FIG. 23.

Since, in case of 1EC system, yₙ-locator 13a is set in an inactive state, the output of index/binary converting parts 443 and 444 is 15; and the output of index/binary converting parts 433 and 434 is 31. At this time, the output of 4-bit adder 445 becomes 15+15≡0(mod 15); and the output of 5-bit adder 435 becomes 31+31≡11(mod 17). Therefore, to give “0” to the following i-locator 13b, with NAND gates G11 and G12, to which mode select signal 2EC is input, forcedly set C3 and D2 corresponding to 11 to be “0” in case of 1EC system.

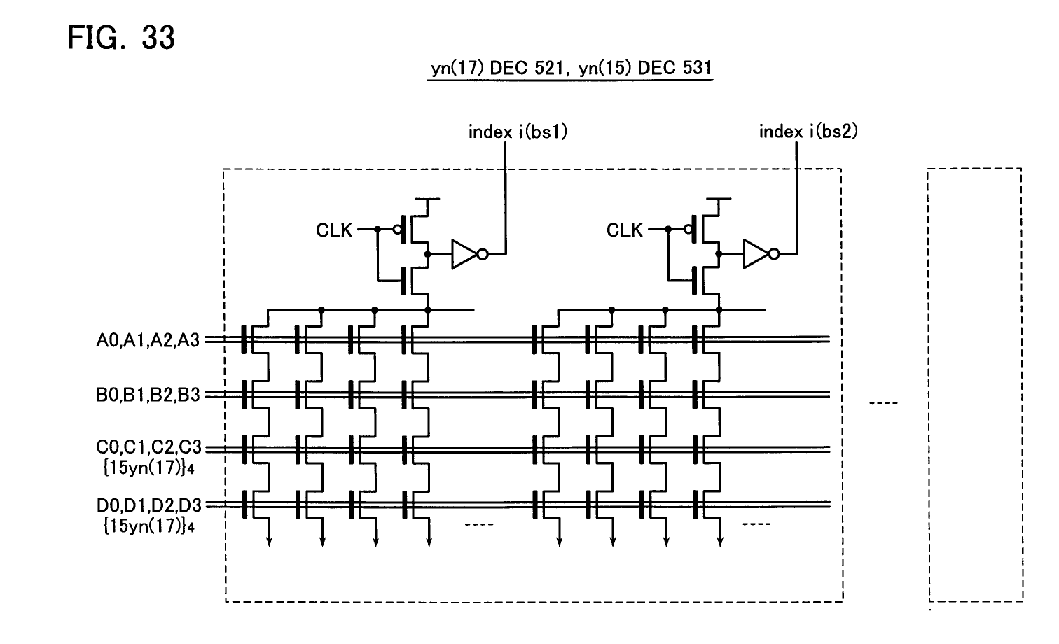

FIG. 33 shows a configuration of yₙ(17) decoding part 521 and yₙ(15) decoding part 531 in the i-locator 13b. This is basically the same as the 17σ₃ decoding part 442 in the yₙ-locator 13a, and formed to select two remainder class indexes in correspondence with two errors. Therefore, to prevent simultaneously selected two index signals from being in collision with each other, the same remainder class index “index i” is delivered to the different buses bs1 and bs2 as two components, “index i(bs1)” and “index i(bs2)”.

The elements of remainder classes are those of 17 and 15, and defined by 9-bit binary data. Since the uppermost output {15yₙ(17)}₄ of the 5-bit(17) adder becomes “1” only when the remainder by modulo 17 is 16, {15yₙ(17)}4 is used in place of signals Ci and Di when the element of the remainder class is 16. As a result, the decoding part may be formed of 4-string NAND circuits.

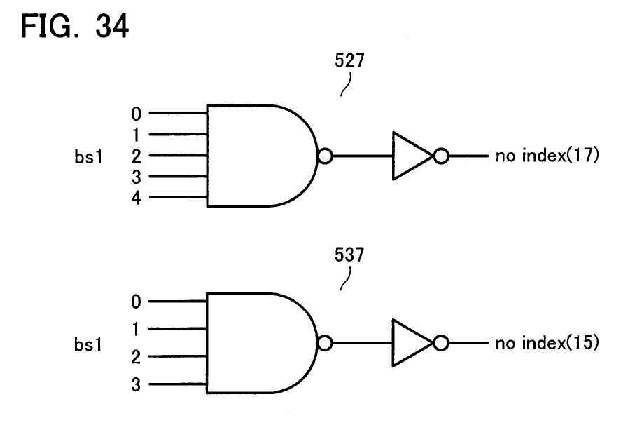

In case there are no remainder class indexes, it is impossible to perform error location searching. It is no-index detecting parts 527 and 537 to detect the situation. These are, as shown in FIG. 34, formed of NAND circuits each for detecting all bit of the index/binary converted output is “1”. Since the same signals are output simultaneously on the buses bs1 and bs2, it is sufficient to monitor either one of them, for example, only the state of bus bs1.

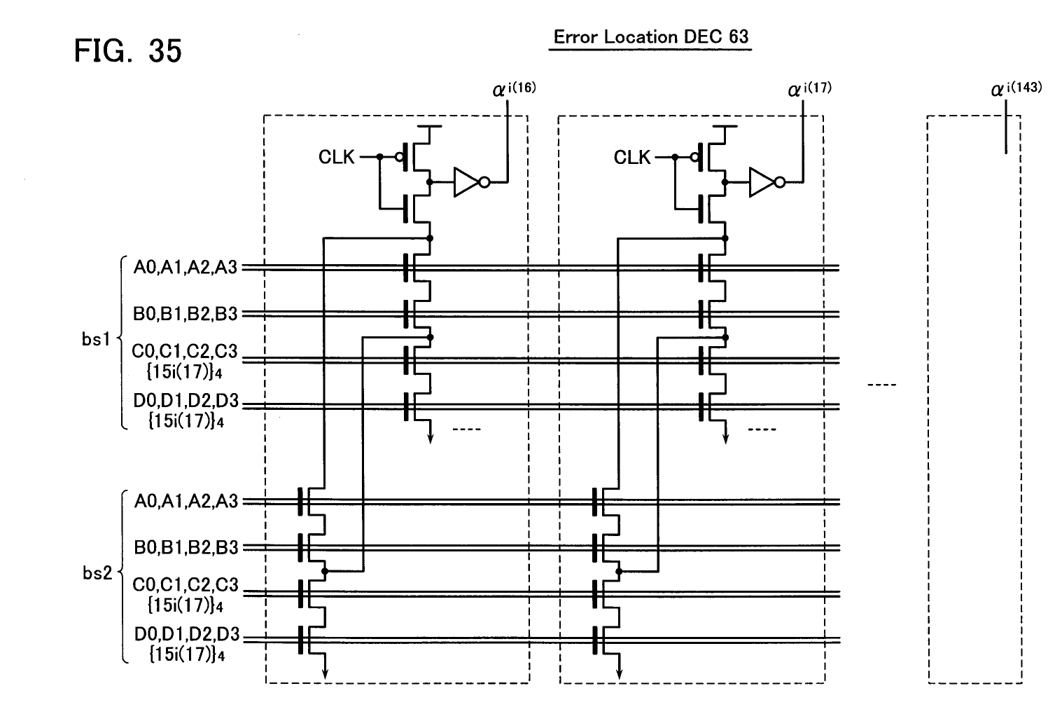

FIG. 35 shows error location decoder 63 in the error correction part 14, which decodes the pre-decoded signals Ai, Bi, Ci, Di and {15i(17)}₄ on the buses bs1 and bs2 to output error location signal α^{i(k)}.

Why the output {15i(17)}₄ of the 5-bit(17) adders 526, 528, which is not pre-decoded, is used is because the remainder class element is 16 like the yₙ(17) decoder. Since the combination of Ai, Bi, Ci and Di is not dependent on the buses bs1 and bs2, NAND circuits for Ai, Bi on the buses bs1 and bs2 are connected in parallel, and those for Ci, Di on the buses bs1 and bs2 are also connected in parallel.

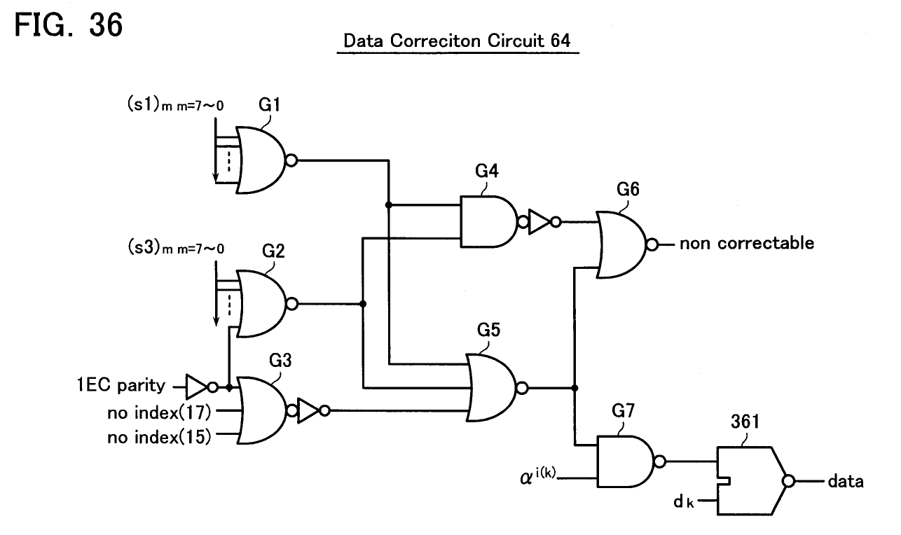

FIG. 36 shows the data correction circuit 64, which functions in different ways in accordance with 1EC and 2EC. In case of 2EC system, if syndrome coefficient S₁×S₃ is not “0”, there is generated one error or more. In case of S₁×S₃=0, there are two situations as follows: if S₁=S₃=0, there is no error, and data correction is not required; if only one of S₁ and S₃ is 0, there are three bits or more errors, and data correction is impossible. Further, if no-index(17) or n-index(15) is “1”, it designates that error location search is impossible, and there are three bits or more errors. Therefore, data correction is impossible.

To judge the above-described situations, there are prepared NOR gates G1 and G2 for detecting that syndrome coefficients (s1)ₘ and (s3)ₘ are in a all “0” state, respectively. If there are three bits or more errors, either one of the outputs of these NOR gates G1 and G2 becomes “0”. In response to it, NOR gate G6 outputs “1” to designate that correction is impossible (i.e., “non-correctable”). At this time, NOR gate G5 outputs “0”, and this makes NAND gate G7 inactive, which is used for error correction decoding.

If no error, both outputs of the gate G1 and G2 become “1”, so that gates G4 and G5 output “0”, and this makes the decode use NAND gate G7 inactive.

If one or two bits errors, both outputs of the gate G1 and G2 become “0”, so that the output “1” of the NOR gate G5 makes the decode use NAND gate G7 active. Disposed as a data inverting circuit for inverting data dₖ at the selected error location α^{i(k)} is 2-bit parity check circuit 361, which outputs data dₖ as it is when there are no errors, and inverted it at the error location.

In case of 1EC system, the syndrome coefficient s3 does not become “0” because of the syndrome calculation circuit arrangement, and signals No-index(17) and No-index(15) are set to be “0”. Therefore, when “1EC parity” is “1” (i.e., 1EC mode) except that S₁ is zero, the gate G5 outputs “H”, whereby error correction is performed. If “1EC parity” is “0”, there are 2-bit errors, so that “non-correctable” signal will be output.

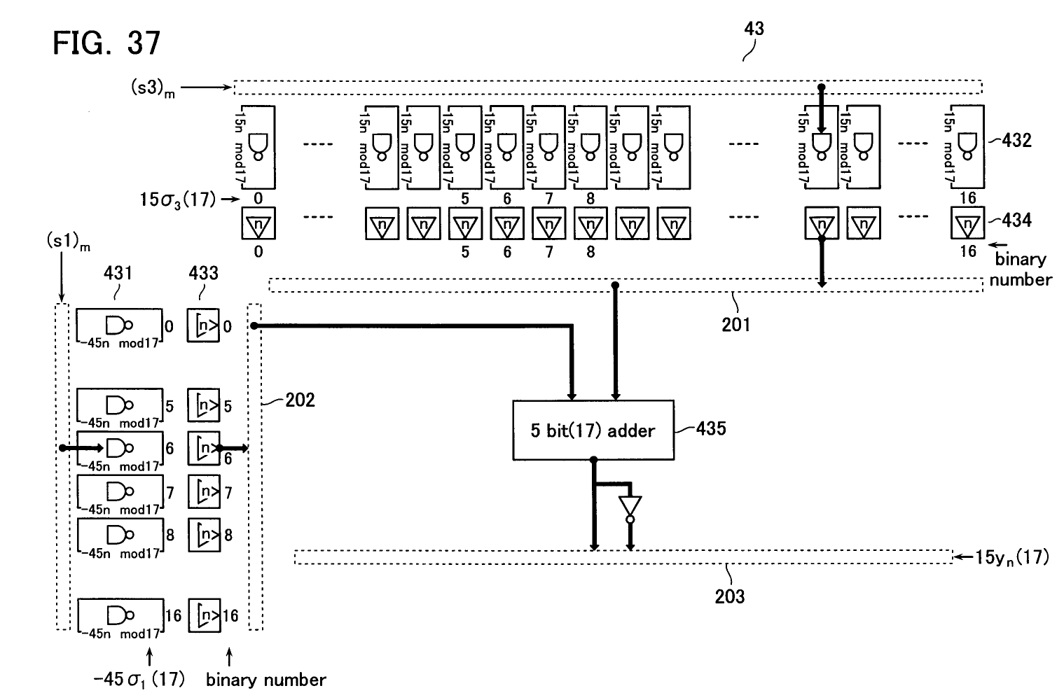

FIG. 37 shows a detailed example of one index adder part 43 in the yₙ-locator 13a. This index adder part 43 is for performing addition with modulo 17, i.e., for obtaining the remainder class index 15σ₃-45σ₁, (mod 17) based on the syndrome indexes σ₃ and σ₁.

Disposed on one input side of index σ₃ are decoding parts 432 for decoding the coefficients (s3)ₘ (m=0 to 7) of 7-degree remainder polynomial obtained by the syndrome calculation to select an input signal corresponding to a remainder class index position of 15σ₃ with modulo 17. To convert the index to binary number, index/binary converting parts 434 are disposed to output 5-bit binary number to the bus 201. There are 17 selecting circuits here because of modulo 17.

Disposed on the other input-side of index σ₁ are decoding parts 431 for decoding the coefficients (s1)ₘ (m=0 to 7) of 7-degree remainder polynomial obtained by the syndrome calculation to select an input signal corresponding to a remainder class index position of −45σ₁ with modulo 17. To convert the index to binary number, index/binary converting parts 433 are disposed to output 5-bit binary number to the bus 202. There are 17 selecting circuits here because of modulo 17.

Binary data output to the buses 201 and 202 are input to a 5-bit(17) adder 435, the sum of which is output to bus 203. This output is binary data of the index, which designates the remainder class of 15yₙ with modulo 17.

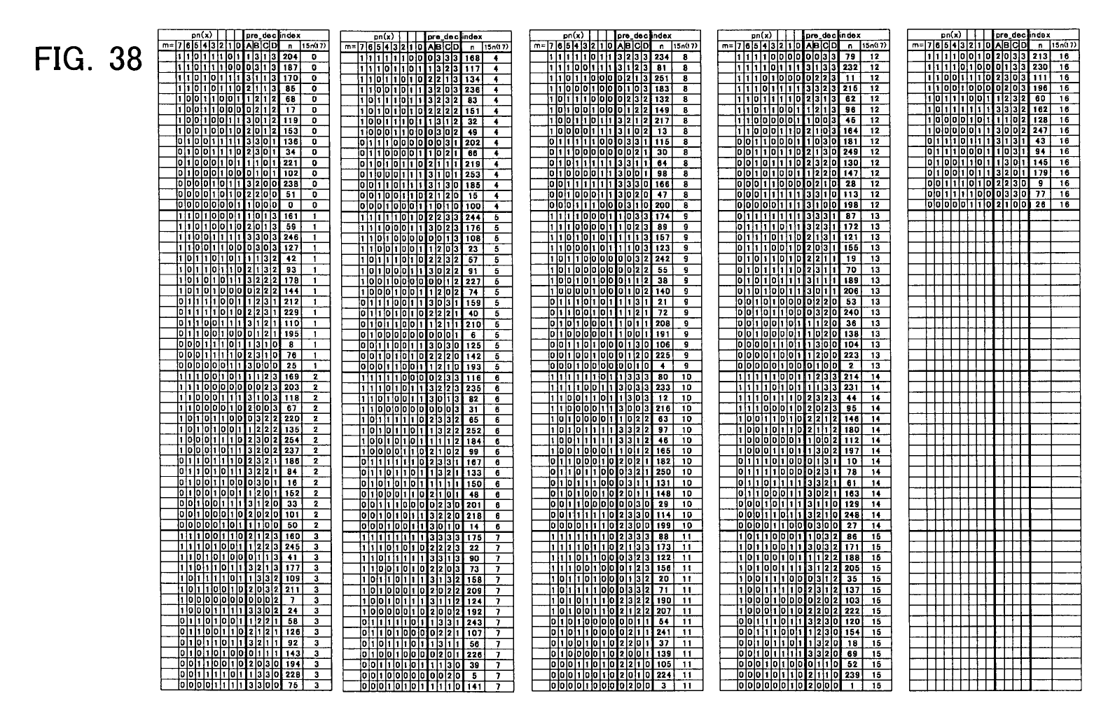

FIG. 38 shows the remainder class 15n(17) with modulo 17, which is obtained by multiplying index “n” of the irreducible polynomial pⁿ(x) by 15, and classifying the result into indexes 0 to 16. 15 “n”s are included in each class. Ai, Bi, Ci and Di are pre-decoded in accordance with coefficients of the respective degrees of the polynomial pⁿ(x), and “i” (=0, 1, 2 or 3) of these signals is shown in the table.

Gate wirings disposed at decode transistors in the index adder part 43 are selectively coupled to the respective gates in accordance with signals Ai, Bi, Ci and Di. For example, in case of index 1, NAND nodes to be coupled in parallel (NOR coupled) correspond to those of n=161, 59, 246, 127, 42, 93, 178, 144, 212, 229, 110, 195, 8, 76 and 25, and the corresponding signals Ai, Bi, Ci and Di are coupled to transistor gates of NAND circuits.

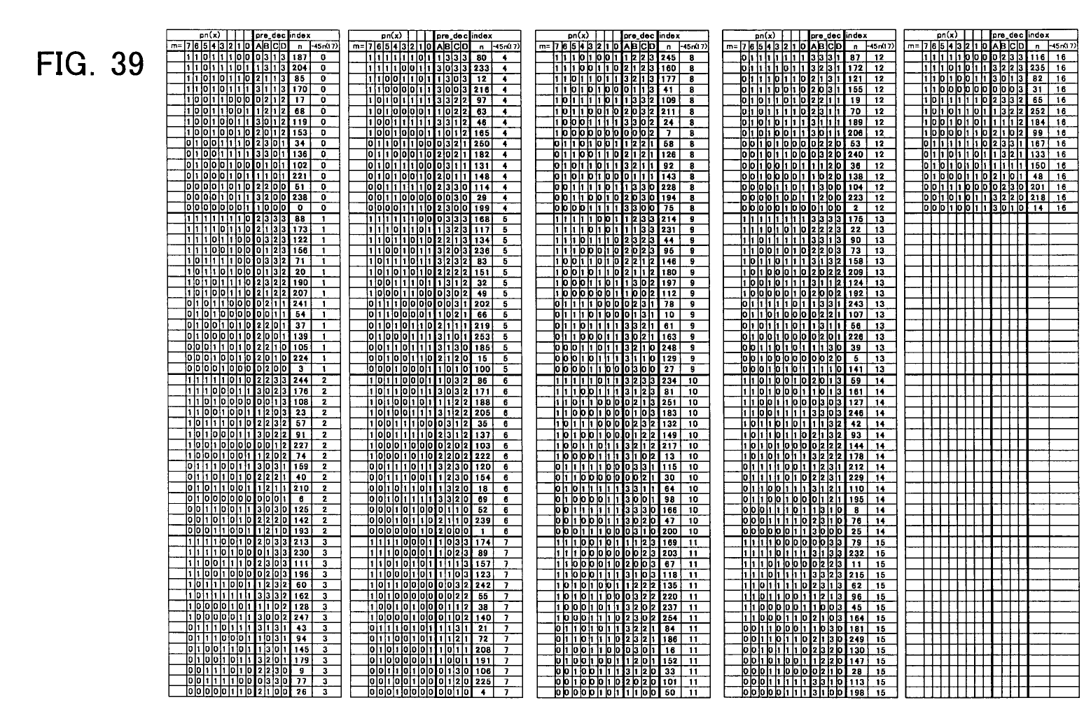

FIG. 39 shows the remainder class −45n (17) with modulo 17, which is obtained by multiplying index “n” of the irreducible polynomial pⁿ(x) by −45, and classifying the result into indexes 0 to 16. 15 “n”s are included in each class. Ai, Bi, Ci and Di are pre-decoded in accordance with coefficients of the respective degrees of the polynomial pⁿ(x), and “i” (=0, 1, 2 or 3) of these signals is shown in the table.

Gate wirings disposed at decode transistors in the index adder part 43 are selectively coupled to the respective gates in accordance with signals Ai, Bi, Ci and Di. For example, in case of index 1, NAND nodes to be coupled in parallel (NOR coupled) correspond to those of n=88, 173, 122, 156, 71, 20, 190, 207, 241, 54, 37, 139, 105, 224 and 3, and the corresponding signals Ai, Bi, Ci and Di are coupled to transistor gates of NAND circuits.

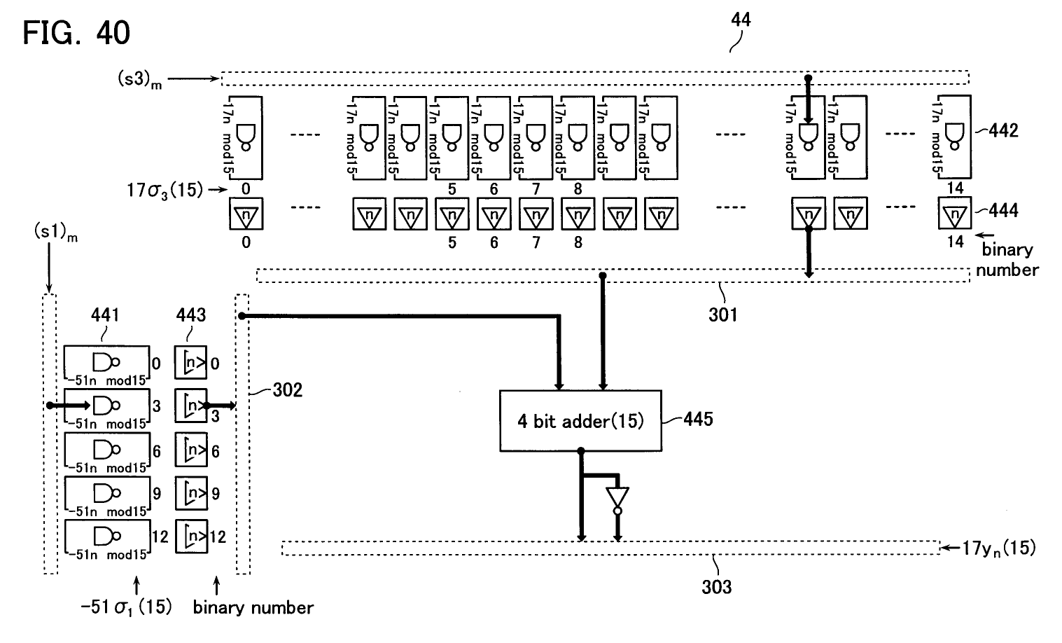

FIG. 40 shows a detailed example of the other index adder part 44 in the yₙ-locator 13a. This index adder part 44 is for performing addition with modulo 15, i.e., for obtaining the remainder class index 17σ₃-51σ₁ (mod 15) based on the syndrome indexes σ₃ and σ₁.

Disposed on one input side of index σ₃ are decoding parts 442 for decoding the coefficients (s3)ₘ (m=0 to 7) of 7-degree remainder polynomial obtained by the syndrome calculation to select an input signal corresponding to a remainder class index position of 17σ₃ with modulo 15. To convert the index to binary number, index/binary converting parts 444 are disposed to output 5-bit binary number to the bus 301. There are 15 selecting circuits here because of modulo 15.

Disposed on the other input side of index σ₁ are decoding parts 441 for decoding the coefficients (s1)ₘ(m=0 to 7) of 7-degree remainder polynomial obtained by the syndrome calculation to select an input signal corresponding to a remainder class index position of −51σ₁, with modulo 15. To convert the index to binary number, index/binary converting parts 443 are disposed to output 5-bit binary number to the bus 302. Since 15 and 51 includes common prime 3, the number of the remainder classes is 15/3=5. Therefore, there are prepared 5 selecting circuits here.

Binary data output to the buses 301 and 302 are input to a 4-bit(15) adder 445, the sum of which is output to bus 303. This output is binary data of the index, which designates the remainder class of 17yₙ with modulo 15.

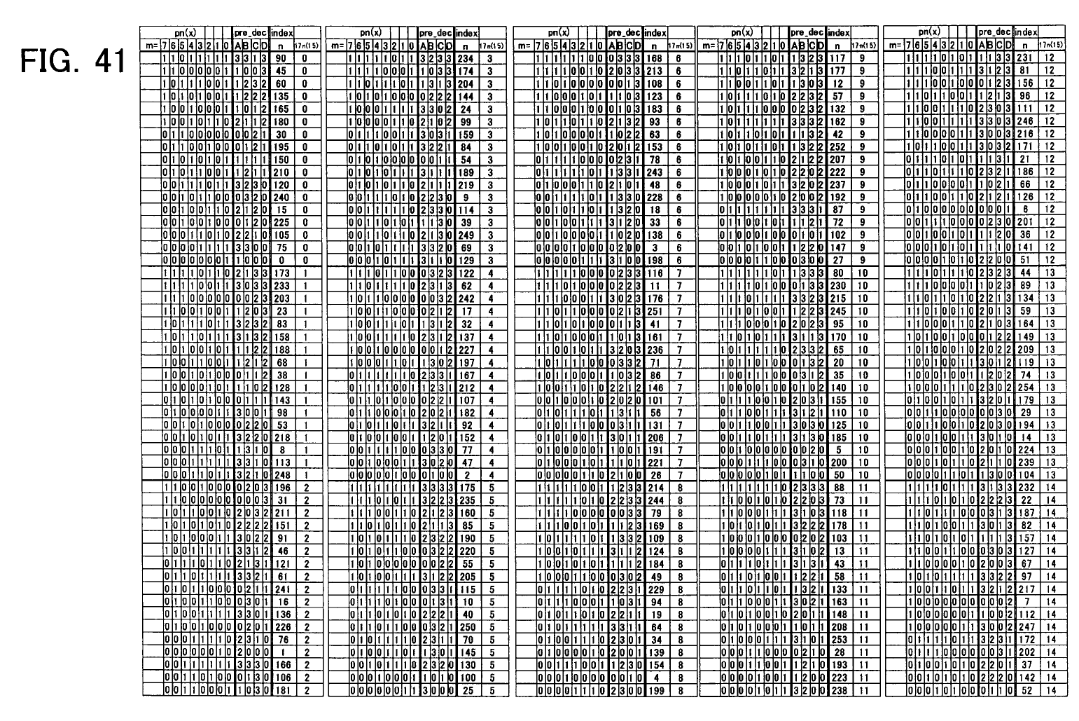

FIG. 41 shows the remainder 17n(15) with modulo 15, which is obtained by multiplying index “n” of the irreducible polynomial pⁿ(x) by 17, and classified the result into indexes 0 to 14. 17 “n”s are included in each class. Ai, Bi, Ci and Di are pre-decoded in accordance with coefficients of the respective degrees of the polynomial pⁿ(x), and “i” (=0, 1, 2 or 3) of these signals is shown in the table.

For example, in case of index 1, NAND nodes to be coupled in parallel (NOR coupled) correspond to those of n=173, 233, 203, 23, 83, 158, 188, 68, 38, 128, 143, 98, 53, 218, 8, 113 and 248, and the corresponding signals Ai, Bi, Ci and Di are coupled to transistor gates of NAND circuits.

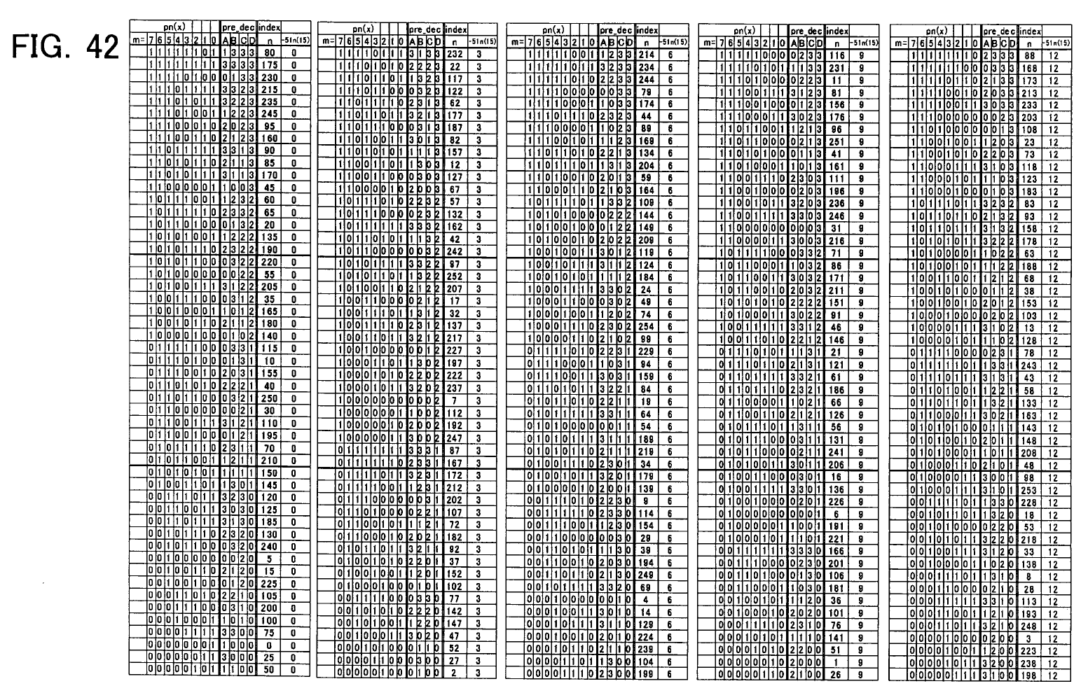

FIG. 42 shows the remainder −51n(15) with modulo 15, which is obtained by multiplying index “n” of the irreducible polynomial pⁿ(x) by −51, and classified the result into indexes 0, 3, 6, 9 and 12. 51 “n”s are included in each class. Ai, Bi, Ci and Di are pre-decoded in accordance with coefficients of the respective degrees of the polynomial pⁿ(x), and “i” (=0, 1, 2 or 3) of these signals is shown in the table.

Gate wirings disposed at decode transistors in the index adder part 44 are selectively coupled to the respective gates in accordance with signals Ai, Bi, Ci and Di. For example, in case of index 3, NAND nodes to be coupled in parallel (NOR coupled) correspond to those of n=232, 22, 117, 122, 62, . . . , 47, 52, 27 and 2, and the corresponding signals Ai, Bi, Ci and Di are coupled to transistor gates of NAND circuits.

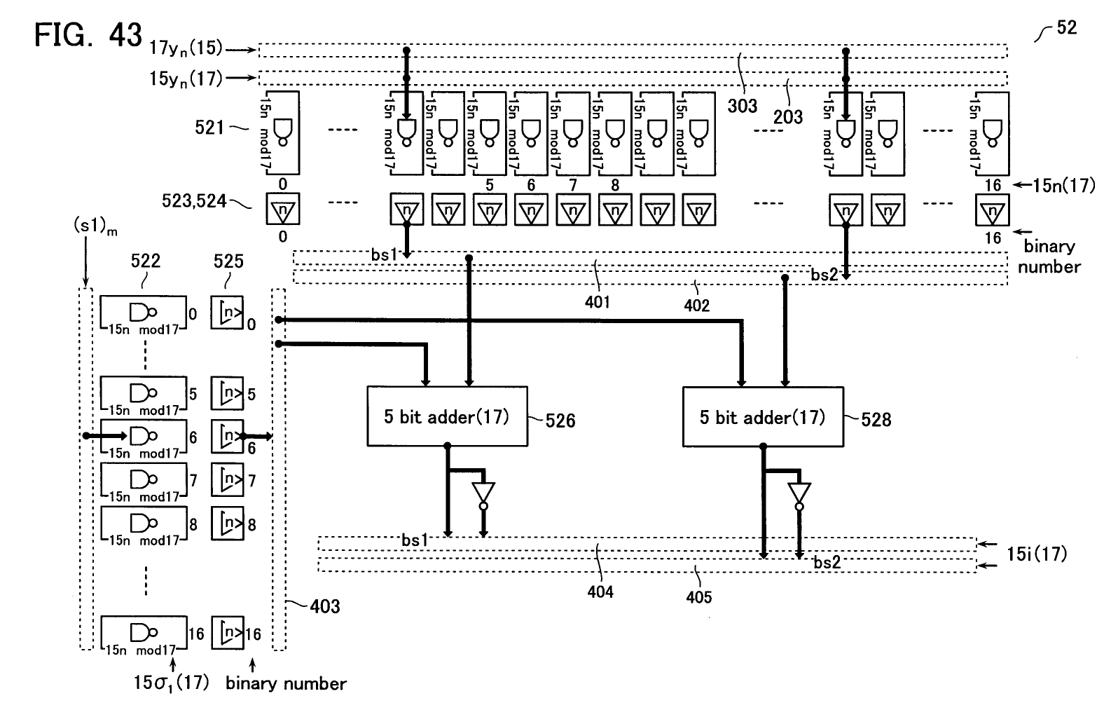

FIG. 43 shows one index adder part 52 in the i-locator 13b, which is for obtaining 15n+15σ₁ (mod 17) corresponding to the real error location based on the syndrome index σ₁.

One inputs are 15yₙ(17) and 17yₙ(15), which are remainder indexes expressed by binary data on the buses 203 and 303, respectively. These inputs are decoded at decoding parts 521, and the obtained remainder class index 15n(17) are converted to binary data and output to buses 401 and 402 through index/binary converting parts 523 and 524. There are 17 selecting circuits because of modulo 17.

Since the maximum two indexes of 15n(17) are obtained from 17yₙ(15) and 15yₙ(17), there are prepared two 5-bit(17) adders 526 and 528. Since it is in need of preventing the two inputs from being in collision with each other, the decoding parts are formed to satisfy this condition.

Disposed on the other input side of σ₁, decoding parts 522 for decoding the coefficients (s1)ₘ (m=0 to 7) of the 7-degree polynomial obtained by the syndrome calculation to select a remainder index 15σ₁(17). The decoded index is converted to binary data and output to bus 403 via index/binary converting parts 525. There are 17 selecting circuits because of modulo 17.

The numbers on the buses 401 and 402 and that on the bus 403 are input to adders 526 and 528, which output binary data designating a remainder class index corresponding to 15i(mod 17) in the table shown in FIG. 38 to buses 404 and 405.

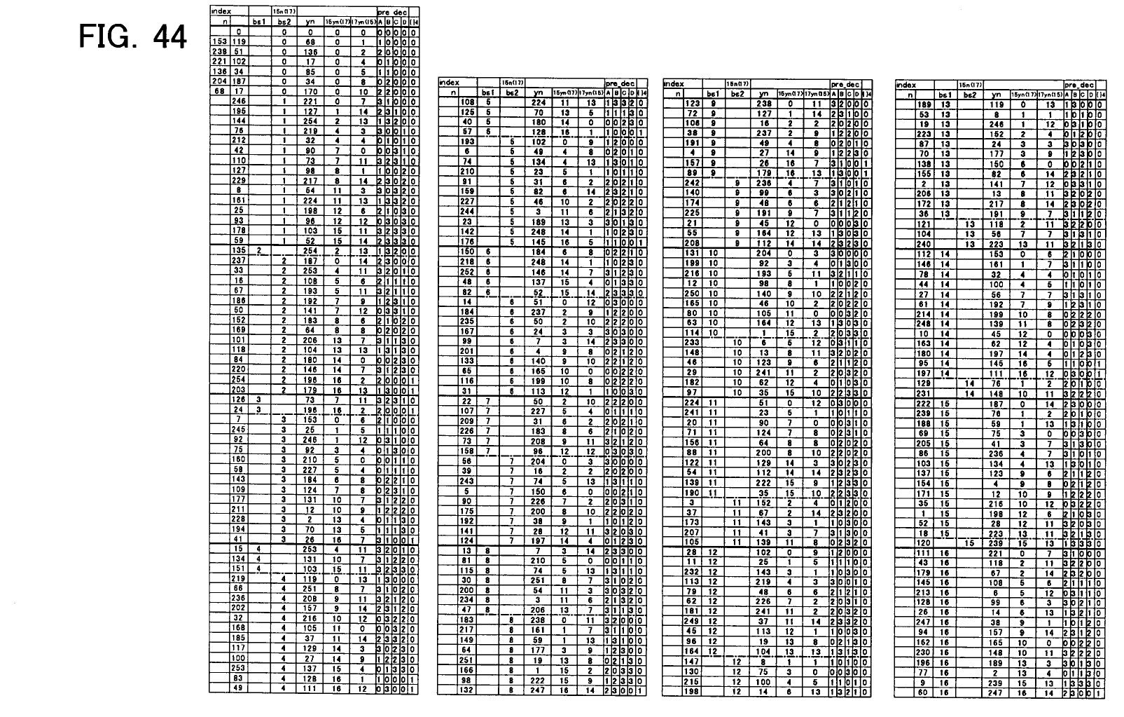

FIG. 44 shows the relationship between the remainder classes 15yₙ(17), 17yₙ(15) and 15n(17). Further shown in FIG. 44 are elements of “yₙ” and “n” corresponding to the remainder classes. Actually used for decoding are only the remainder classes.

Further shown in the column 15n(17) are indexes, which are delivered to two buses bs1 and bs2. This shows that two of 15n(17) simultaneously selected from the pair of {15yₙ(17), 17yₙ(15)} always belong to different buses from each other. By way of exception, there is a case of {15yₙ(17), 17yₙ(15)]={0, 0}. In this case, which designates one bit error, “0” is delivered to both of buses bs1 and bs2, thereby preventing the adders 526 and 528 from erroneously outputting “2-bit errors”.

With the exception of this, for example, {15yₙ(17), 17yₙ(15)}={11, 13}, {13, 5}, {14, 0}, {16, 1}, {0, 9}, {4, 8}, {4, 13}, {5, 1}, {6, 2}, {6, 14}, {10, 23}, {13, 5}, {14, 0}, {16, 1} are correspond to the remainder class 15n(17)-5, in which {11, 13}, {13, 5}, {14, 0} and {16, 1} are coupled to the bus bs1; and the remaining to the bus bs2. That is, the decoding parts are formed based on these groups.

Further shown in the table are value “i” of the signals Ai, Bi, Ci and Di and bit {15yₙ(17)}₄ corresponding “16” with such an expression as { }4.

In accordance with this table, the gates of decoder NAND portions 15yₙ(17) and 17yₙ(15) of two 5-bit adders are coupled, so that binary numbers of 15n(17) are output to the buses bs1 and bs2.

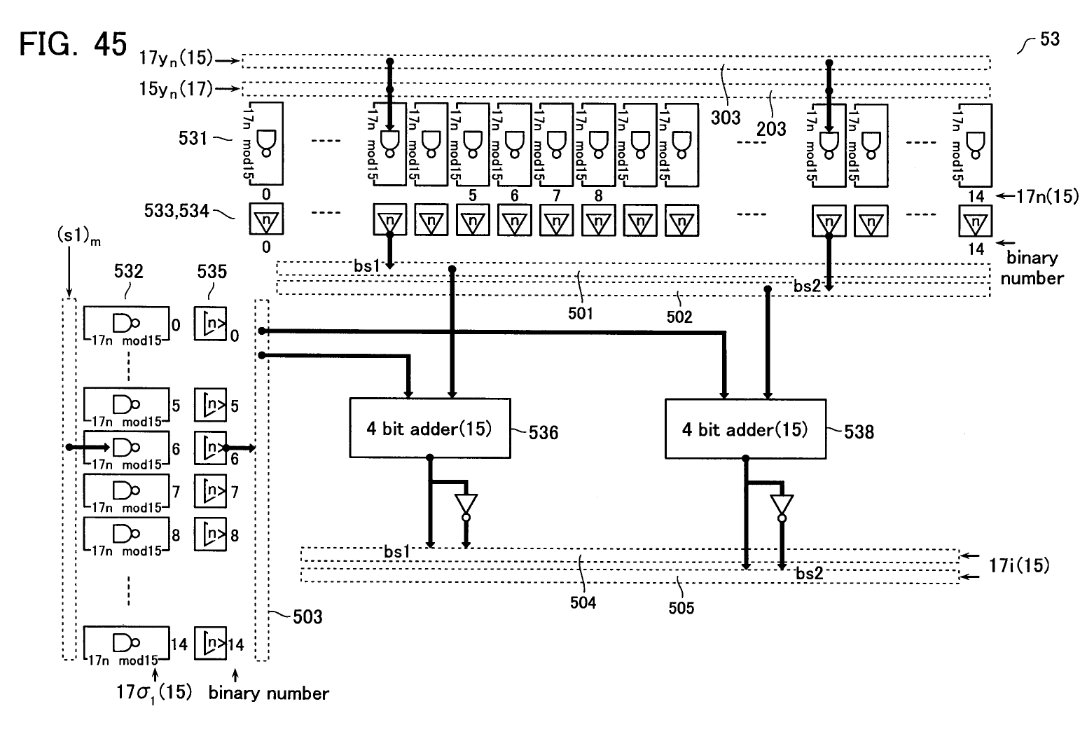

FIG. 45 shows the other index adder part 53 in the i-locator 13b, which is for obtaining 17n+17σ₁ (mod 15) corresponding to the real error location based on the syndrome index σ₁.

One inputs are the remainder indexes expressed by binary data on the buses 203 and 303, respectively. These inputs are decoded at decoding parts 531, and the obtained remainder class indexes 17n(15) are converted to binary data and output to buses 501 and 502 through index/binary converting parts 533 and 534. There are 15 selecting circuits because of modulo 15.

Since the maximum two indexes of 17n(15) are obtained from 17yₙ(15) and 15yₙ(17), there are prepared two 4-bit(15) adders 536 and 538. It is in need of preventing the two inputs from being in collision with each other. The decoding parts are formed to satisfy the above-described condition.

Disposed on the other input side of σ₁, decoding parts 532 for decoding the coefficients (s1)ₘ (m=0 to 7) of the 7-degree polynomial obtained by the syndrome calculation to select a remainder index 17σ₁(15). The decoded index is converted to binary data and output to bus 503 via index/binary converting parts 535. There are 15 selecting circuits because of modulo 15.

The outputs on the buses 501 and 502 and that on the bus 503 are input to adders 536 and 538, which output binary data designating a remainder class index corresponding to 17i(mod 15) in the table shown in FIG. 41 to buses 504 and 505.

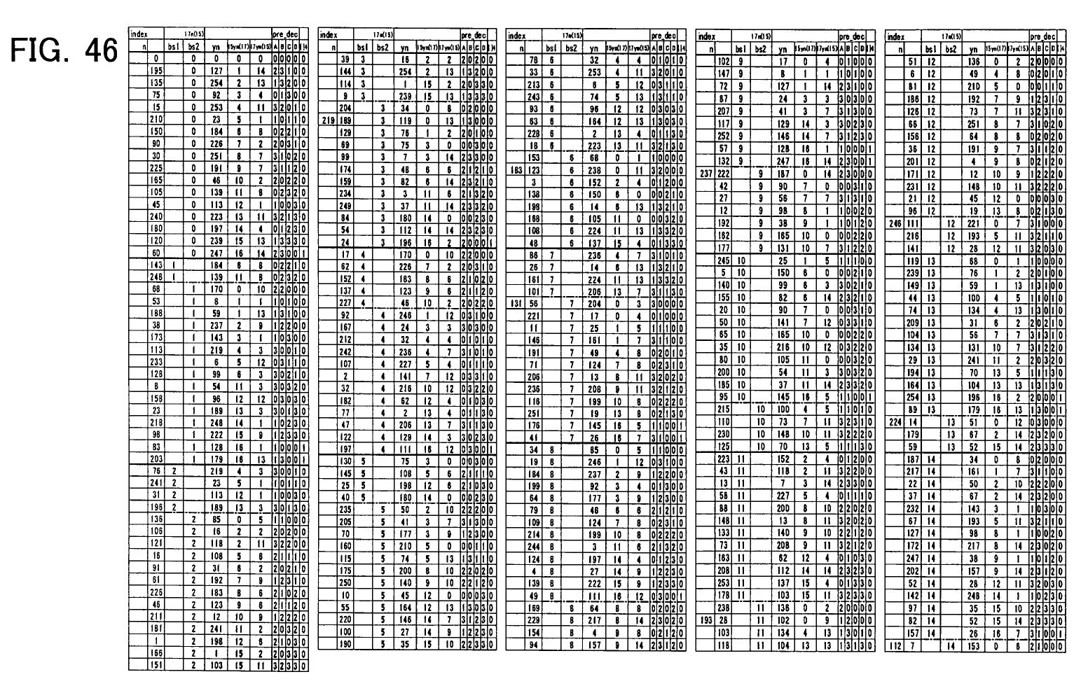

FIG. 46 shows the relationship between the remainder classes 15yₙ(17), 17yₙ(15) and 17n(15). Further shown in FIG. 46 are elements of “yₙ” and “n” corresponding to the remainder classes. Actually used for decoding are only the remainder classes.

Further shown in the column 17n(15) are indexes, which are delivered to two buses bs1 and bs2. This shows that two of 17n(15) simultaneously selected from the pair of {15yₙ(17), 17yₙ(15)} always belong to different buses from each other. By way of exception, there is a case of {15yₙ(17), 17yₙ(15)]={0, 0}. In this case, which designates one bit error, “0” is delivered to both of buses bs1 and bs2, thereby preventing the adders 536 and 538 from erroneously outputting “2-bit errors”.

With the exception of this, for example, {15yₙ(17), 17yₙ(15)}={2, 2}, {2, 13}, {15, 2}, {15, 13}, {0, 8}, {0, 13}, {1, 2}, {3, 0}, {3, 14}, {6, 6}, {6, 14}, {11, 14}, {14, 0}, {14, 14} and {16, 2} are correspond to the remainder class 17n(15)=3, in which {2, 2}, {2, 13}, {15, 2} and {15, 13} are coupled to the bus bs1; and the remaining to the bus bs2. That is, the decoding parts are formed based on these groups.

Further shown in the table are value “i” of the signals Ai, Bi, Ci and Di and bit {15yₙ(17)}₄ corresponding “16” with such an expression as { }₄.

In accordance with this table, the gates of decoder NAND portions 15yₙ(17) and 17yₙ(15) in the two adders 536 and 538 are coupled, so that binary numbers of 17n(15) are output to the buses bs1 and bs2.

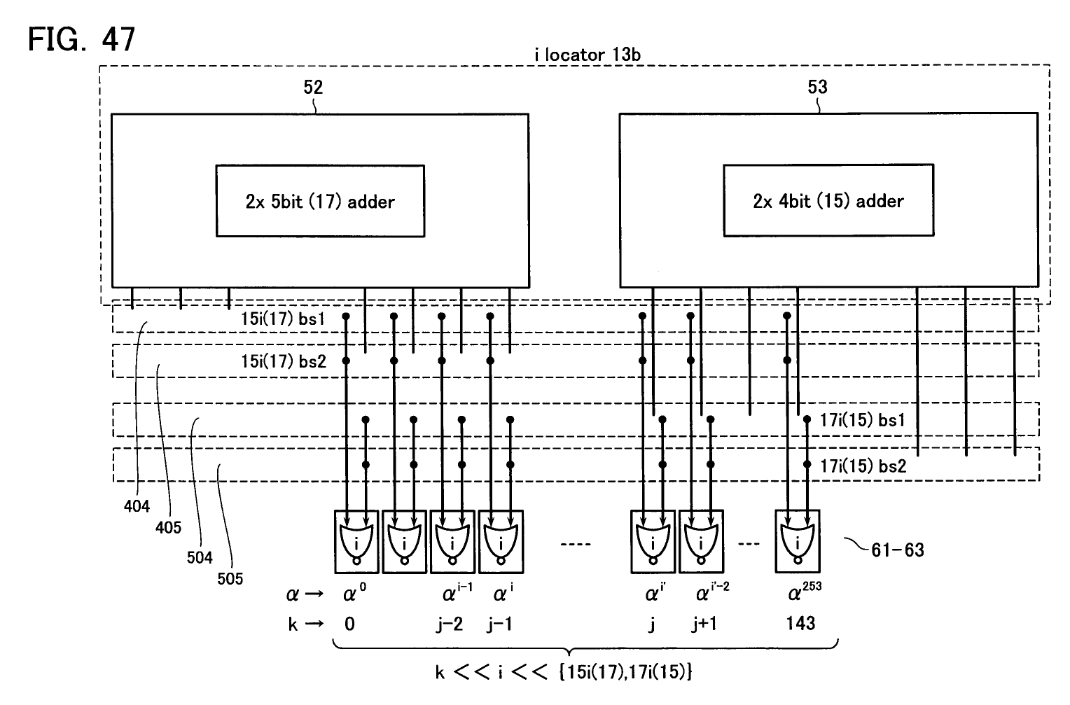

FIG. 47 shows such a part that integrates the operation results of the index adder parts 52 and 53 in the i-locator 13b and converts the error location “y” to the real error bit location, i.e., portions corresponding to the pre-decoders 61, 62 and error correction decoder 63 shown in FIG. 22. Outputs 15i(17) and 17i(15) of the index adders 52 and 53 are output to the respective two buses bs1 and bs2. It is possible to designate only one “i” based on NAND-NOR logic, and “k” based on the combination of {15i(17), 17i(15)} from the relationships between “k”, “i”, 15i(17) and 17i(15). Operation result of αⁱ becomes the final output. One or two selected “k”s designate up to 2-bit errors.

FIG. 48 shows a table, in which bit location indexes “i” are arranged in order of the physical position “k” for showing the relationship between “k”, “i”, 15i(17) and 17i(15). Further shown in FIG. 48 are the remainder indexes {15i(17), 17i(15)} corresponding to the respective “i”s, “i” of the pre-decoded outputs Ai, Bi, Ci and Di, and bit {15i(17)}₄ corresponding to “16”, which is shown as { }₄.

### [Application Devices]

As an embodiment, an electric card using the non-volatile semiconductor memory devices according to the above-described embodiments of the present invention and an electric device using the card will be described bellow.

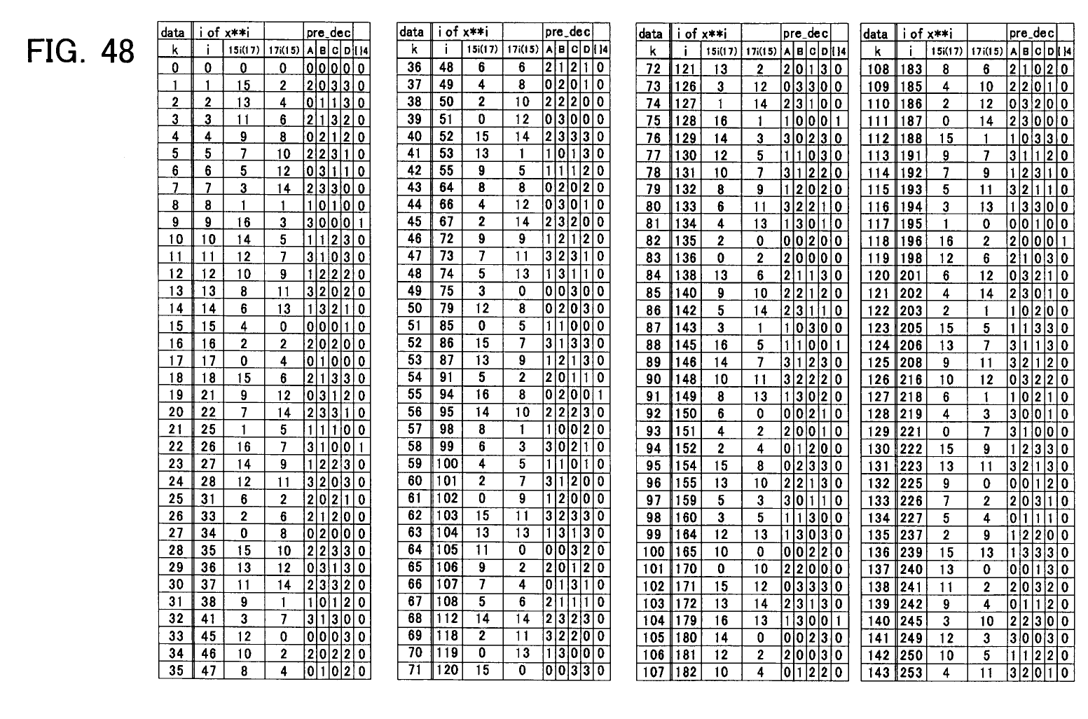

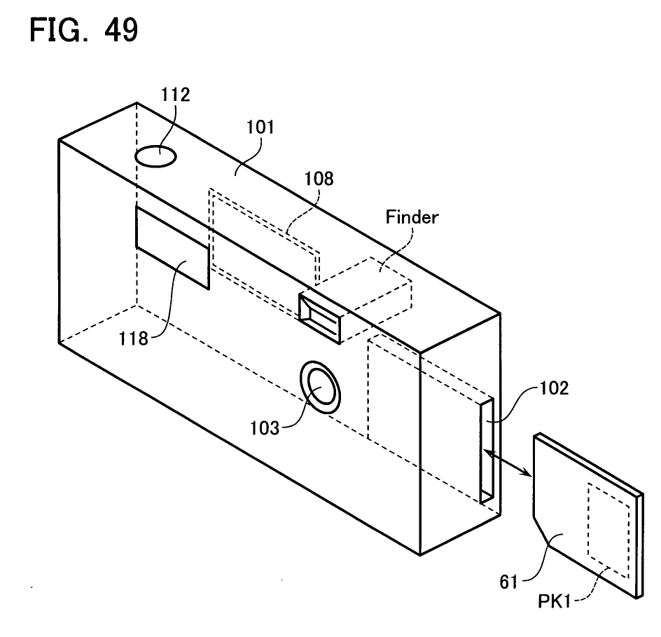

FIG. 49 shows an electric card according to this embodiment and an arrangement of an electric device using this card. This electric device is a digital still camera 101 as an example of portable electric devices. The electric card is a memory card 61 used as a recording medium of the digital still camera 101. The memory card 61 incorporates an IC package PK1 in which the non-volatile semiconductor memory device or the memory system according to the above-described embodiments is integrated or encapsulated.

The case of the digital still camera 101 accommodates a card slot 102 and a circuit board (not shown) connected to this card slot 102. The memory card 61 is detachably inserted in the card slot 102 of the digital still camera 101. When inserted in the slot 102, the memory card 61 is electrically connected to electric circuits of the circuit board.

If this electric card is a non-contact type IC card, it is electrically connected to the electric circuits on the circuit board by radio signals when inserted in or approached to the card slot 102.

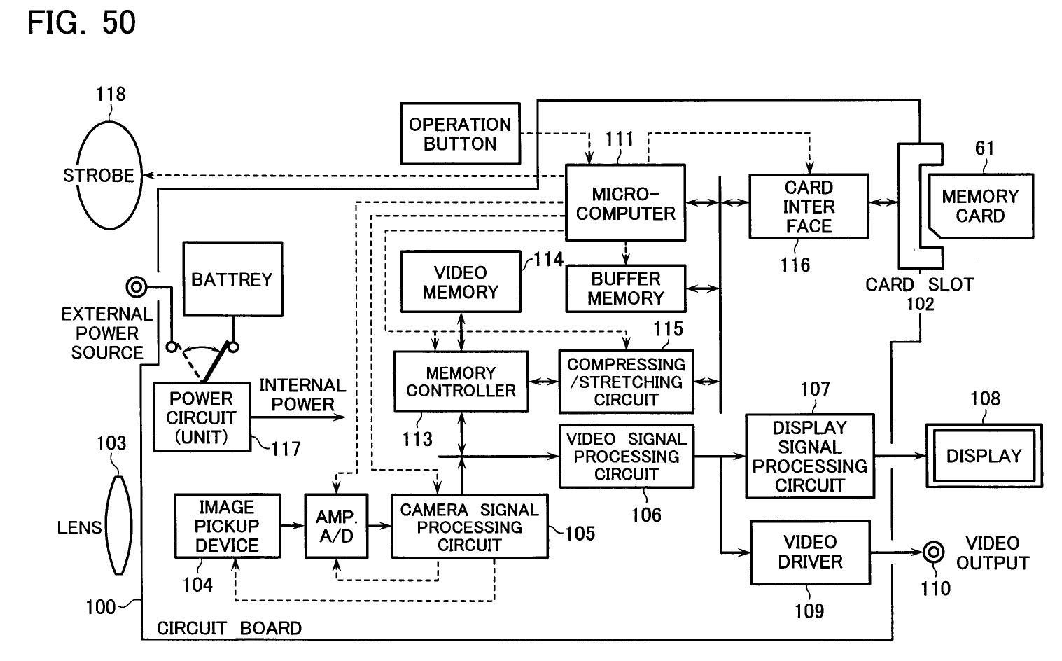

FIG. 50 shows a basic arrangement of the digital still camera. Light from an object is converged by a lens 103 and input to an image pickup device 104. The image pickup device 104 is, for example, a CMOS sensor and photoelectrically converts the input light to output, for example, an analog signal. This analog signal is amplified by an analog amplifier (AMP), and converted into a digital signal by an A/D converter (A/D). The converted signal is input to a camera signal processing circuit 105 where the signal is subjected to automatic exposure control (AE), automatic white balance control (AWB), color separation, and the like, and converted into a luminance signal and color difference signals.

To monitor the image, the output signal from the camera processing circuit 105 is input to a video signal processing circuit 106 and converted into a video signal. The system of the video signal is, e.g., NTSC (National Television System Committee). The video signal is input to a display 108 attached to the digital still camera 101 via a display signal processing circuit 107. The display 108 is, e.g., a liquid crystal monitor.

The video signal is supplied to a video output terminal 110 via a video driver 109. An image picked up by the digital still camera 101 can be output to an image apparatus such as a television set via the video output terminal 110. This allows the pickup image to be displayed on an image apparatus other than the display 108. A microcomputer 111 controls the image pickup device 104, analog amplifier (AMP), A/D converter (A/D), and camera signal processing circuit 105.

To capture an image, an operator presses an operation button such as a shutter button 112. In response to this, the microcomputer 111 controls a memory controller 113 to write the output signal from the camera signal processing circuit 105 into a video memory 114 as a flame image. The flame image written in the video memory 114 is compressed on the basis of a predetermined compression format by a compressing/stretching circuit 115. The compressed image is recorded, via a card interface 116, on the memory card 61 inserted in the card slot.

To reproduce a recorded image, an image recorded on the memory card 61 is read out via the card interface 116, stretched by the compressing/stretching circuit 115, and written into the video memory 114. The written image is input to the video signal processing circuit 106 and displayed on the display 108 or another image apparatus in the same manner as when image is monitored.

In this arrangement, mounted on the circuit board 100 are the card slot 102, image pickup device 104, analog amplifier (AMP), A/D converter (A/D), camera signal processing circuit 105, video signal processing circuit 106, display signal processing circuit 107, video driver 109, microcomputer 111, memory controller 113, video memory 114, compressing/stretching circuit 115, and card interface 116.

The card slot 102 need not be mounted on the circuit board 100, and can also be connected to the circuit board 100 by a connector cable or the like.

A power circuit 117 is also mounted on the circuit board 100. The power circuit 117 receives power from an external power source or battery and generates an internal power source voltage used inside the digital still camera 101. For example, a DC-DC converter can be used as the power circuit 117. The internal power source voltage is supplied to the respective circuits described above, and to a strobe 118 and the display 108.

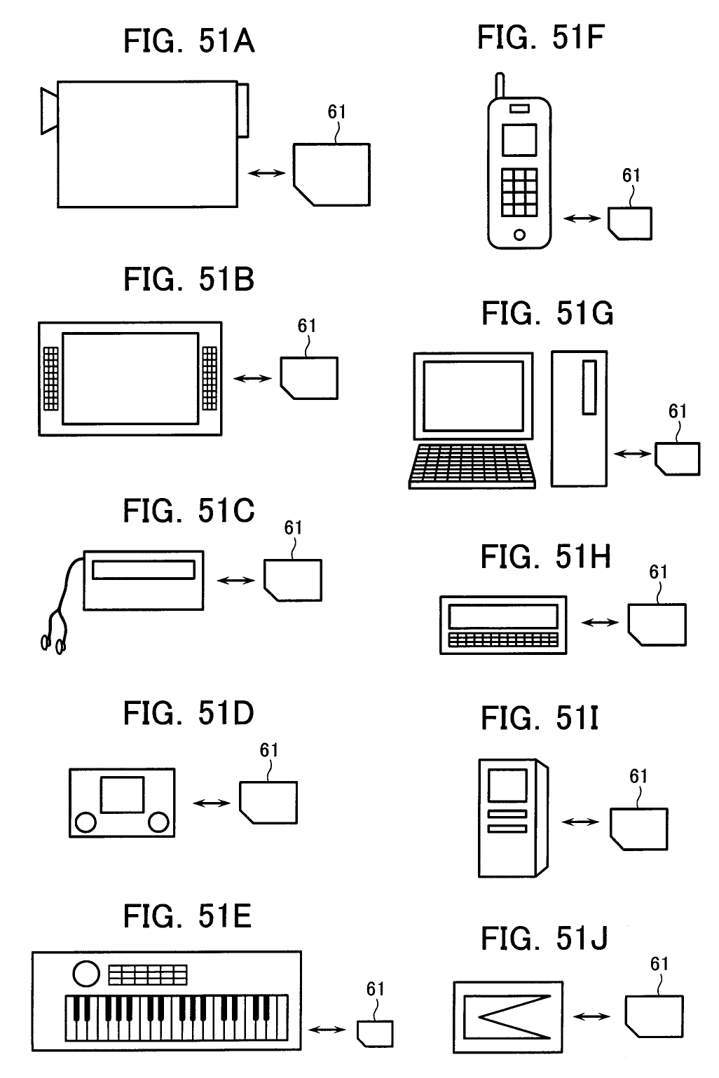

As described above, the electric card according to this embodiment can be used in portable electric devices such as the digital still camera explained above. However, the electric card can also be used in various apparatus such as shown in FIGS. 51A to 51J, as well as in portable electric devices. That is, the electric card can also be used in a video camera shown in FIG. 51A, a television set shown in FIG. 51B, an audio apparatus shown in FIG. 51C, a game apparatus shown in FIG. 51D, an electric musical instrument shown in FIG. 51E, a cell phone shown in FIG. 51F, a personal computer shown in FIG. 51G, a personal digital assistant (PDA) shown in FIG. 51H, a voice recorder shown in FIG. 51I, and a PC card shown in FIG. 51J.

This invention is not limited to the above-described embodiment. It will be understood by those skilled in the art that various changes in form and detail may be made without departing from the spirit, scope, and teaching of the invention.

What is claimed is:

1. A semiconductor memory device comprising an error detection and correction system, wherein
the error detection and correction system has a first operation mode for correcting one number-bit errors and a second operation mode for correcting another number-bit error(s), which are exchangeable to be set with a main portion of the system used in common.

2. The semiconductor memory device according to claim 1, wherein
the first and second operation modes are exchanged to be set for different data areas from each other in the memory device.

3. The semiconductor memory device according to claim 1, wherein
the first and second operation modes are selectively set for a common data area in the memory device.

4. The semiconductor memory device according to claim 1, wherein
the error detection and correction system is formed as a 2-bit error correcting system with a BCH code over Galois field GF(2ⁿ) used in the first operation mode, which has an encoding part for generating error detecting-use check bits based on to-be-written data, the encoding part comprising: a set of parity check circuits; and an input circuit for selecting input data input to the respective parity check circuits, and wherein
in the second operation mode, the input circuit is changed in construction for a certain portion necessary for the second operation mode in the set of the parity check circuits, and inputs of the remaining parity check circuits are fixed in potential.

5. The semiconductor memory device according to claim 1, wherein
the error detection and correction system is formed as a 2-bit error correcting system with a BCH code over Galois field GF(2ⁿ) used in the first operation mode, which has a syndrome operation part for calculating syndromes based on the read out data, the syndrome operation part comprising: a set of parity check circuits; and an input circuit for selecting input data input to the respective parity check circuits, and wherein
in the second operation mode, the input circuit is changed in construction for a certain portion necessary for the second operation mode in the set of the parity check circuits, and inputs of the remaining parity check circuits are fixed in potential.

6. The semiconductor memory device according to claim 1, wherein
the error detection and correction system is formed as a 2-bit error correcting system with a BCH code over Galois field GF(2ⁿ) used in the first operation mode, which has an error location searching part with an operation circuit for performing addition/subtraction with modulo 2ⁿ−1, the operation circuit including: a first adder circuit for performing addition/subtraction with modulo A; and a second adder circuit for performing addition/subtraction with modulo B (where, A and B are prime factors obtained by factorizing 2ⁿ−1), the first and second adder circuits performing addition/subtraction simultaneously in parallel with each other to output an operation result of the addition/subtraction with modulo 2ⁿ−1, and wherein
in the second operation mode, part of the operation circuit is made inactive.

7. The semiconductor memory device according to claim 1, wherein
the error detection and correction system is configured with a BCH code over Galois field GF(2ⁿ), and wherein
the BCH code is configured in such a manner that a certain number of degrees are selected as information bits to be simultaneously error-correctable in the memory device from the entire degree of an information polynomial with degree numbers corresponding to error correctable maximum bit numbers.

8. The semiconductor memory device according to claim 1, wherein
the semiconductor memory device is a non-volatile memory, in which electrically rewritable and non-volatile memory cells are arranged.

9. The semiconductor memory device according to claim 8, wherein
the non-volatile memory has a cell array with NAND cell units arranged therein, the NAND cell unit having a plurality of memory cells connected in series.

10. The semiconductor memory device according to claim 8, wherein
the non-volatile memory stores such multi-level data that two or more bits are stored in each memory cell.

11. A semiconductor memory device comprising a cell array with electrically rewritable and non-volatile semiconductor memory cells arranged therein and an error detection and correction system, which is correctable up to 2-bit errors for read out data of the cell array by use of a BCH code over Galois field GF(256), wherein
the error detection and correction system has a first operation mode for correcting 2-bit errors and a second operation mode for correcting 1-bit error, which are exchangeable to be set with a main portion of the system used in common.

12. The semiconductor memory device according to claim 11, wherein
the first and second operation modes are exchanged to be set for different data areas from each other in the cell array.

13. The semiconductor memory device according to claim 11, wherein
the first and second operation modes are selectively set for a common data area in the cell array.

14. The semiconductor memory device according to claim 11, wherein
the error detection and correction system comprises:
an encoding part configured to generate check bits to be written into the cell array together with to-be-written data;
a syndrome operation part configured to execute syndrome operation for read out data of the cell array;
an error location searching part configured to search error location in the read out data based on the operation result of the syndrome operation part; and
an error correcting part configured to invert an error bit in the read out data detected in the error location searching part, and output it.

15. The semiconductor memory device according to claim 14, wherein
the encoding part comprises a set of parity check circuits and an input circuit for selecting input data input to the respective parity check circuits, which are used in the first operation mode, and wherein
in the second operation mode, the input circuit is changed in construction for a certain portion necessary for the second operation mode in the set of the parity check circuits, and inputs of the remaining parity check circuits are fixed in potential.

16. The semiconductor memory device according to claim 14, wherein
the syndrome operation part comprises a set of parity check circuits and an input circuit for selecting input data input to the respective parity check circuits, which are used in the first operation mode, and wherein
in the second operation mode, the input circuit is changed in construction for a certain portion necessary for the second operation mode in the set of the parity check circuits, and inputs of the remaining parity check circuits are fixed in potential.

17. The semiconductor memory device according to claim 14, wherein
the error location searching part comprises an operation circuit for performing addition/subtraction with modulo 2ⁿ−1, which includes a first adder circuit for performing addition/subtraction with modulo A, and a second adder circuit for performing addition/subtraction with modulo B (where, A and B are prime factors obtained by factorizing 2ⁿ−1), the first and second adder circuits performing addition/subtraction simultaneously in parallel with each other to output an operation result of the addition/subtraction with modulo 2ⁿ−1 in the first operation mode, and wherein
in the second operation mode, part of the operation circuit is made inactive.

18. The semiconductor memory device according to claim 11, wherein
the BCH code is configured in such a manner that a certain number of degrees are selected as information bits to be simultaneously error-correctable in the memory device from the entire degree of an information polynomial with degree numbers corresponding to error correctable maximum bit numbers.

19. The semiconductor memory device according to claim 11, wherein
in the cell array, a plurality of memory cells are connected in series to constitute a NAND cell unit.

20. The semiconductor memory device according to claim 11, wherein
the cell array stores such multi-level data that two or more bits are stored in each memory cell.
